(19) United States
(12) Patent Application Publication
(10) Pub. No.: US 2025/0169211 A1
(43) Pub. Date: May 22, 2025

(54) SEMICONDUCTOR DEVICE, PHOTODETECTOR DEVICE, AND ELECTRONIC APPARATUS

(71) Applicant: SONY SEMICONDUCTOR SOLUTIONS CORPORATION, Kanagawa (JP)

(72) Inventors: Yuki KAWAHARA, Kanagawa (JP); Hideomi KUMANO, Kanagawa (JP)

(73) Assignee: SONY SEMICONDUCTOR SOLUTIONS CORPORATION, Kanagawa (JP)

(21) Appl. No.: 18/841,027

(22) PCT Filed: Jan. 20, 2023
(86) PCT No.: PCT/JP2023/001613

§ 371 Date: Aug. 23, 2024

(30) Foreign Application Priority Data
Mar. 8, 2022 (JP) 2022-035522

(51) Int. Cl. H10F 39/00

(52) U.S. Cl. CPC H10F 39/80377; H10F 39/011; H10F 39/811

(57) ABSTRACT

A semiconductor device capable of achieving both short channel suppression and suppression of variations in transistor characteristics that includes a semiconductor substrate and a field-effect transistor on the semiconductor substrate. The field-effect transistor includes a diffusion layer region in which a channel is formed, a gate electrode covering at least a part of the diffusion layer region and having a side wall facing a side surface of the diffusion layer region and a top plate facing an upper surface of the diffusion layer region, a source region connected to one side of the gate electrode, and a drain region connected to the other side of the gate electrode portion. The side wall and the top plate of the gate electrode have a self-aligned structure. The source region and the drain region are formed to be self-aligned by implanting impurities obliquely into the side wall portion of the gate electrode portion.

### TECHNICAL FIELD

The present disclosure relates to a semiconductor device, a photodetector device, and an electronic apparatus including the photodetector device.

### BACKGROUND ART

Conventionally, as a photodetector device, solid-state imaging elements such as charge coupled device (CCD) and complementary metal oxide semiconductor (CMOS) image sensors have been widely used in, for example, electronic apparatuses having an imaging function, such as a digital still camera and a digital video camera. The photodetector device includes pixels in which a photodiode (photoelectric conversion element) that performs photoelectric conversion and a transistor are combined, and an image is formed on the basis of pixel signals output from the plurality of pixels arranged two-dimensionally.

For example, in the solid-state imaging element, a charge accumulated in the photodiode is transferred via a transfer transistor to a floating diffusion (FD) portion having a predetermined capacitance and provided in a connection portion between the photodiode and a gate electrode of an amplifier transistor. Then, a pixel signal corresponding to an amount of charges accumulated in the FD portion is read from the pixel.

In general, noise generated in the amplifier transistor is directly added to a pixel signal and is output, and thus image quality deteriorates. An influence of 1/f generated in the amplifier transistor is large in particular, and, in order to improve the image quality of the solid-state imaging element, it is necessary to suppress generation of 1/f noise. It is known that the 1/f noise depends on a gate length and a gate width, and increasing the size of the amplifier transistor is effective for reducing the 1/f noise. As such a solid-state imaging element, for the purpose of noise reduction, there has been proposed a solid-state imaging element that adopts a FinFET having an embedded gate structure in which a part of a gate electrode is embedded (e.g., Patent Document 1).

### CITATION LIST

### Patent Document

Patent Document 1: Japanese Patent Application Laid-Open No. 2021-34435

### SUMMARY OF THE INVENTION

### Problems to be Solved by the Invention

In Patent Document 1, SiO2 is formed beside a fin, and a portion corresponding to a channel of a transistor is dug to form a gate electrode. The gate electrode has a non-self-aligned structure in which a side wall portion embedded in the dug portion and a top plate portion parallel to a fin top are individually formed.

In the non-self-aligned structure, the side wall portion of the gate electrode is biased with respect to source/drain portions, and the electric field becomes non-uniform. Further, when impurity implantation energy of the source and the drain is increased in order to use the entire fin as effectively as possible, diffusion occurs in a depth direction, and thus short channel suppression becomes difficult.

The present disclosure has been made in view of such circumstances, and an object thereof is to provide a semiconductor device, a photodetector device, and an electronic apparatus capable of achieving both short channel suppression and suppression of variations in transistor characteristics.

Further, an object of the present disclosure is to provide a semiconductor device, a photodetector device, and an electronic apparatus capable of improving a failure of penetration of a through contact.

Furthermore, an object of the present disclosure is to provide a semiconductor device, a photodetector device, and an electronic apparatus capable of avoiding a decrease in area efficiency of a second stage of a two-stage pixel.

### Solutions to Problems

An aspect of the present disclosure is a semiconductor device including: a semiconductor substrate; and a field-effect transistor provided on the semiconductor substrate, in which: the field-effect transistor includes a diffusion layer region in which a channel is formed, a gate electrode portion covering at least a part of the diffusion layer region and having a side wall portion facing a side surface of the diffusion layer region and a top plate portion facing an upper surface of the diffusion layer region, a source region provided in the diffusion layer region and connected to one side of the gate electrode portion in a gate length direction of the gate electrode portion, and a drain region provided in the diffusion layer region and connected to the other side of the gate electrode portion in the gate length direction of the gate electrode portion; the side wall portion and the top plate portion of the gate electrode portion have a self-aligned structure; and the source region and the drain region are formed to be self-aligned by implanting impurities obliquely into the side wall portion of the gate electrode portion.

Another aspect of the present disclosure is a photodetector device including: a first substrate portion including a photoelectric conversion element; and a second substrate portion layered on a surface of the first substrate portion, the surface being opposite to a light incident surface of the first substrate portion, and including a readout circuit that outputs a pixel signal based on a charge output from the photoelectric conversion element, in which: a field-effect transistor provided in the readout circuit includes a diffusion layer region in which a channel is formed, a gate electrode portion covering at least a part of the diffusion layer region and having a side wall portion facing a side surface of the diffusion layer region and a top plate portion facing an upper surface of the diffusion layer region, a source region provided in the diffusion layer region and connected to one side of the gate electrode portion in a gate length direction of the gate electrode portion, and a drain region provided in the diffusion layer region and connected to the other side of the gate electrode portion in the gate length direction of the gate electrode portion; the side wall portion and the top plate portion of the gate electrode portion have a self-aligned structure; and the source region and the drain region are formed to be self-aligned by implanting impurities obliquely into the side wall portion of the gate electrode portion.

Furthermore, another aspect of the present disclosure is an electronic apparatus including a photodetector device including a first substrate portion including a photoelectric conversion element, and a second substrate portion layered on a surface of the first substrate portion, the surface being opposite to a light incident surface of the first substrate portion, and including a readout circuit that outputs a pixel signal based on a charge output from the photoelectric conversion element, in which: a field-effect transistor provided in the readout circuit includes a diffusion layer region in which a channel is formed, a gate electrode portion covering at least a part of the diffusion layer region and having a side wall portion facing a side surface of the diffusion layer region and a top plate portion facing an upper surface of the diffusion layer region, a source region provided in the diffusion layer region and connected to one side of the gate electrode portion in a gate length direction of the gate electrode portion, and a drain region provided in the diffusion layer region and connected to the other side of the gate electrode portion in the gate length direction of the gate electrode portion; the side wall portion and the top plate portion of the gate electrode portion have a self-aligned structure; and the source region and the drain region are formed to be self-aligned by implanting impurities obliquely into the side wall portion of the gate electrode portion.

### BRIEF DESCRIPTION OF DRAWINGS

FIG. 1 is a schematic diagram depicting a configuration example of a photodetector device according to a first embodiment of the present disclosure.

FIG. 2 is a circuit diagram depicting a configuration example of a pixel unit of the photodetector device in FIG. 1.

FIG. 3 is a cross-sectional view of a first substrate and a second substrate on which the pixel unit in FIG. 2 is formed.

FIG. 4 is a perspective view of a field-effect transistor according to a comparative example of the first embodiment.

FIG. 5A is a cross-sectional view (part 1) depicting a comparative example of the first embodiment.

FIG. 5B is a cross-sectional view (part 2) depicting a comparative example of the first embodiment.

FIG. 5C is a cross-sectional view (part 3) depicting a comparative example of the first embodiment.

FIG. 6 is a perspective view of a field-effect transistor according to the first embodiment of the present disclosure.

FIG. 7 is a plan view (part 1) depicting steps of forming the field-effect transistor according to the first embodiment of the present disclosure.

FIG. 8 is a plan view (part 2) depicting steps of forming the field-effect transistor according to the first embodiment of the present disclosure.

FIG. 9 is a cross-sectional view depicting a state of forming a drain portion and a source portion as a second embodiment of the present disclosure.

FIG. 10 is a plan view of a readout circuit according to a third embodiment of the present disclosure.

FIG. 11 is a cross-sectional view taken along line A in FIG. 10.

FIG. 12 is a cross-sectional view taken along line B in FIG. 10.

FIG. 13 is a cross-sectional view taken along line C in FIG. 10.

FIG. 14A is a cross-sectional view (part 1) depicting a method of manufacturing a photodetector device according to the third embodiment of the present disclosure in order of steps.

FIG. 14B is a cross-sectional view (part 2) depicting the method of manufacturing the photodetector device according to the third embodiment of the present disclosure in order of steps.

FIG. 14C is a cross-sectional view (part 3) depicting the method of manufacturing the photodetector device according to the third embodiment of the present disclosure in order of steps.

FIG. 14D is a cross-sectional view (part 4) depicting the method of manufacturing the photodetector device according to the third embodiment of the present disclosure in order of steps.

FIG. 14E is a cross-sectional view (part 5) depicting the method of manufacturing the photodetector device according to the third embodiment of the present disclosure in order of steps.

FIG. 15 is a plan view of a readout circuit in a photodetector device according to a fourth embodiment of the present disclosure.

FIG. 16 is a cross-sectional view taken along line D in FIG. 15.

FIG. 17A is a cross-sectional view (part 1) of a readout circuit according to a comparative example of the fourth embodiment.

FIG. 17B is a cross-sectional view (part 2) of a readout circuit according to a comparative example of the fourth embodiment.

FIG. 18 is a cross-sectional view of the readout circuit according to the fourth embodiment of the present disclosure.

FIG. 19A is a cross-sectional view (part 1) depicting a method of manufacturing the photodetector device according to the fourth embodiment of the present disclosure in order of steps.

FIG. 19B is a cross-sectional view (part 2) depicting the method of manufacturing the photodetector device according to the fourth embodiment of the present disclosure in order of steps.

FIG. 19C is a cross-sectional view (part 3) depicting the method of manufacturing the photodetector device according to the fourth embodiment of the present disclosure in order of steps.

FIG. 19D is a cross-sectional view (part 4) depicting the method of manufacturing the photodetector device according to the fourth embodiment of the present disclosure in order of steps.

FIG. 19E is a cross-sectional view (part 5) depicting the method of manufacturing the photodetector device according to the fourth embodiment of the present disclosure in order of steps.

FIG. 19F is a cross-sectional view (part 6) depicting the method of manufacturing the photodetector device according to the fourth embodiment of the present disclosure in order of steps.

FIG. 20 is a cross-sectional view of a readout circuit 22B of a photodetector device according to a fifth embodiment of the present disclosure.

FIG. 21 is a cross-sectional view of a readout circuit 22C of a photodetector device according to a sixth embodiment of the present disclosure.

FIG. 22 is a cross-sectional view of a readout circuit 22C of a photodetector device according to a seventh embodiment of the present disclosure.

FIG. 23 is a cross-sectional view of a readout circuit of a photodetector device according to a comparative example of the seventh embodiment.

FIG. 24 is a cross-sectional view of a readout circuit of a photodetector device according to an eighth embodiment of the present disclosure.

FIG. 25 is a cross-sectional view of a photodetector device according to a ninth embodiment of the present disclosure.

FIG. 26 is a cross-sectional view of a photodetector device according to a tenth embodiment of the present disclosure.

FIG. 27 is a cross-sectional view of a photodetector device according to an eleventh embodiment of the present disclosure.

FIG. 28 is a cross-sectional view of a photodetector device according to a twelfth embodiment of the present disclosure.

FIG. 29 is a block diagram depicting a configuration example of an imaging device as an electronic apparatus to which the present technology is applied.

FIG. 30 is a block diagram depicting an example of schematic configuration of a vehicle control system as an example of a mobile body control system to which the technology according to an embodiment of the present disclosure can be applied.

FIG. 31 depicts an example of installation positions of imaging sections in FIG. 30.

### MODE FOR CARRYING OUT THE INVENTION

Hereinafter, embodiments of the present disclosure will be described with reference to the drawings. In the description of the drawings referred to in the following description, the same or similar parts are denoted by the same or similar reference signs, and redundant description will be omitted. However, it should be noted that the drawings are schematic, and the relationship between thickness and planar dimension, the proportion of thickness of each device or each member, and the like differ from actual ones. Therefore, specific thicknesses and dimensions should be determined in consideration of the following description. Further, it goes without saying that dimensional relationships and ratios are partly different between the drawings.

In this specification, a “first conductivity type” means one of the p-type and the n-type, and a “second conductivity type” means one of the p-type and the n-type different from the “first conductivity type”. Further, “n” or “p” to which “+” or “−” is added means a semiconductor region having a relatively higher or lower impurity density than that of a semiconductor region to which “+” or “−” is not added. However, even in the semiconductor regions to which the same “n” and “n” are added, it does not mean that the impurity densities of the semiconductor regions are exactly the same.

Further, definitions of directions such as upward and downward directions in the following description are merely definitions for convenience of description and do not limit the technical idea of the present disclosure. For example, it goes without saying that, if a target is observed while being rotated by 90°, the upward and downward directions are converted into rightward and leftward directions, and if the target is observed while being rotated by 180°, the upward and downward directions are inverted.

Note that the effects described in the present specification are merely examples and are not limited, and other effects may be provided.

### FIRST EMBODIMENT

### Overall Configuration of Photodetector Device

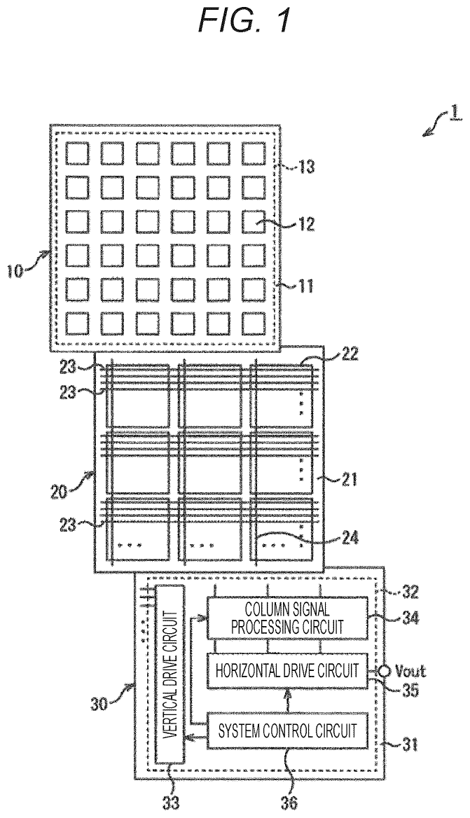

FIG. 1 is a schematic diagram depicting a configuration example of a photodetector device according to a first embodiment of the present disclosure.

As depicted in FIG. 1, a photodetector device 1 is configured by bonding three substrates, i.e., a first substrate 10, a second substrate 20, and a third substrate 30. The first substrate 10, the second substrate 20, and the third substrate 30 are layered in this order.

The first substrate 10 includes a plurality of sensor pixels 12 that performs photoelectric conversion on a first semiconductor substrate 11. The plurality of sensor pixels 12 is provided in a matrix in a pixel region 13 of the first substrate 10. The second substrate 20 includes, on a second semiconductor substrate 21, readout circuits 22 that read out pixel signals based on charges output from the sensor pixels 12, each of which is provided per four sensor pixels 12. The second substrate 20 includes a plurality of pixel drive lines 23 extending in a row direction and a plurality of vertical signal lines 24 extending in a column direction.

The third substrate 30 includes a logic circuit 32 that processes a pixel signal on a third semiconductor substrate 31. The logic circuit 32 includes, for example, a vertical drive circuit 33, a column signal processing circuit 34, a horizontal drive circuit 35, and a system control circuit 36. The logic circuit 32 (specifically, the horizontal drive circuit 35) outputs an output voltage Vout for each sensor pixel 12 to the outside. In the logic circuit 32, a low-resistance region, which is made from a silicide formed by using a self aligned silicide (salicide) process such as CoSi2 or NiSi, may be formed on, for example, a surface of an impurity diffusion region that is in contact with a source electrode and a drain electrode.

The vertical drive circuit 33 sequentially selects the plurality of sensor pixels 12 row by row, for example. The column signal processing circuit 34 performs, for example, correlated double sampling (CDS) processing on the pixel signal output from each sensor pixel 12 in the row selected by the vertical drive circuit 33. For example, the column signal processing circuit 34 extracts a signal level of the pixel signal by performing the CDS processing and holds pixel data corresponding to an amount of light received by each sensor pixel 12. The horizontal drive circuit 35 sequentially outputs the pixel data held in the column signal processing circuit 34 to the outside, for example. The system control circuit 36 controls driving of each block (vertical drive circuit 33, column signal processing circuit 34, and horizontal drive circuit 35) in the logic circuit 32, for example.

### Circuit Configuration Example of Pixel Unit

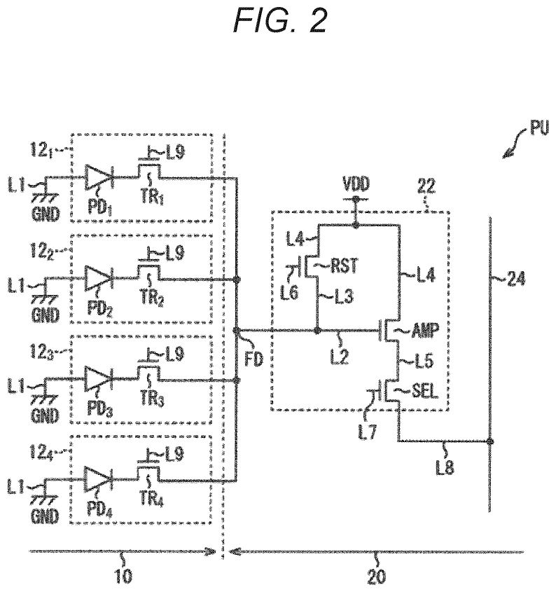

FIG. 2 is a circuit diagram depicting a configuration example of a pixel unit PU of the photodetector device 1.

As depicted in FIG. 2, one pixel unit PU includes four sensor pixels 12 and one readout circuit 22. In other words, one readout circuit 22 is shared by four sensor pixels 12, and outputs of the four sensor pixels 12 are input to the shared readout circuit 22.

Each sensor pixel 12 includes a photodiode PD as a photoelectric conversion element and a transfer transistor TR electrically connected to the photodiode PD.

The readout circuit 22 includes a floating diffusion FD, an amplifier transistor AMP, a reset transistor RST, and a selection transistor SEL. Note that the selection transistor SEL may be omitted as necessary.

Hereinafter, in a case where the four sensor pixels 12 connected to one readout circuit 22 are distinguished, the pixels are described as sensor pixels 121 to 124 as depicted in FIG. 2. The photodiodes PD and the transfer transistors TR included in the sensor pixels 121 to 124 are similarly described as photodiodes PD1 to PD4 and transfer transistors TR1 to TR4. Meanwhile, in a case where it is unnecessary to distinguish the four sensor pixels 12, the photodiodes PD, and the transfer transistors TR, subscripts thereof are omitted.

The photodiode PD generates a charge corresponding to an amount of received light by photoelectric conversion. The cathode of the photodiode PD is electrically connected to the source of the transfer transistor TR, and the anode of the photodiode PD is electrically connected to a reference potential line (e.g., ground). The drain of the transfer transistor TR is electrically connected to the floating diffusion FD, and the gate electrode of the transfer transistor TR is electrically connected to the pixel drive line 23.

An input terminal of the readout circuit 22 is the floating diffusion FD, and the source of the reset transistor RST is electrically connected to the floating diffusion FD. A predetermined power supply voltage VDD is supplied to the drain of the reset transistor RST together with the drain of the amplifier transistor AMP. The gate electrode of the reset transistor RST is electrically connected to the pixel drive line 23 (FIG. 1). The source of the amplifier transistor AMP is electrically connected to the drain of the selection transistor SEL, and the gate electrode of the amplifier transistor AMP is electrically connected to the source of the reset transistor RST. The source of the selection transistor SEL is an output terminal of the readout circuit 22 and is electrically connected to the vertical signal line 24. The gate electrode of the selection transistor SEL is electrically connected to the pixel drive line 23 (FIG. 1).

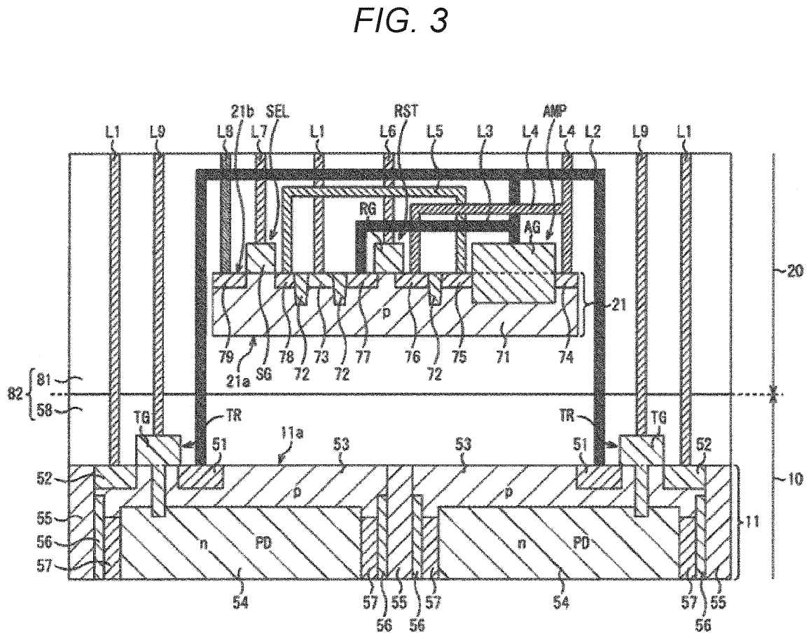

Wires L1 to L9 of FIG. 2 correspond to wires L1 to L9 of FIG. 3 described later.

When the transfer transistor TR is turned on in response to a control signal supplied to the gate electrode via the pixel drive line 23 and the wire L9, the transfer transistor TR transfers a charge of the photodiode PD to the floating diffusion FD. The floating diffusion FD temporarily holds the charge output from the photodiode PD via the transfer transistor TR. The reset transistor RST resets a potential of the floating diffusion FD to a predetermined potential. When the reset transistor RST is turned on, the potential of the floating diffusion FD is reset to the power supply voltage VDD.

The amplifier transistor AMP generates a signal of a voltage corresponding to the charge held in the floating diffusion FD as a pixel signal. The amplifier transistor AMP forms a source follower circuit with a load MOS (not depicted) serving as a constant current source and outputs a pixel signal having a voltage corresponding to the level of the charge generated in the photodiode PD. When the selection transistor SEL is turned on, the amplifier transistor AMP amplifies the potential of the floating diffusion FD and outputs a pixel signal having a voltage corresponding to the potential to the column signal processing circuit 34 via the vertical signal line 24. The selection transistor SEL controls an output timing of the pixel signal from the readout circuit 22. That is, when the selection transistor SEL is turned on, the pixel signal having the voltage corresponding to the level of the charge held in the floating diffusion FD can be output.

The transfer transistor TR, the reset transistor RST, the amplifier transistor AMP, and the selection transistor SEL include, for example, an N-type metal oxide semiconductor field effect transistor (MOSFET).

### Layered Configuration Example of Pixel Unit

FIG. 3 is a cross-sectional view of the first substrate 10 and the second substrate 20 on which the pixel unit PU is formed.

Note that the cross-sectional view of FIG. 3 is merely a schematic diagram and does not intend to strictly show the actual structure. The cross-sectional view in FIG. 3 includes a portion in which horizontal positions of a transistor and an impurity diffusion layer are intentionally changed to easily explain the configuration of the pixel unit PU included in the photodetector device 1 on the paper.

For example, in FIG. 3, a high-concentration n-type layer (n-type diffusion layer) 51 that is a part of the floating diffusion FD, a gate electrode TG of the transfer transistor TR, and a high-concentration p-type layer (p-type diffusion layer) 52 are arranged side by side in a lateral direction, but, in an actual structure, the high-concentration n-type layer 51, the gate electrode TG, and the high-concentration p-type layer 52 are arranged in a direction perpendicular to the paper surface in some cases. In this case, one of the high-concentration n-type layer 51 and the high-concentration p-type layer 52 is arranged on the front side of the paper with the gate electrode TG interposed therebetween, and the other of the high-concentration n-type layer 51 and the high-concentration p-type layer 52 is arranged on the back side of the paper.

As depicted in FIG. 3, in the photodetector device 1, the first substrate 10 and the second substrate 20 are layered to form a layered body. The first substrate 10 includes the first semiconductor substrate 11, and the second substrate 20 is layered on a front surface 11a side of the first semiconductor substrate 11. That is, the second substrate 20 is face-to-back bonded to the first substrate 10.

The transfer transistor TR is provided for each sensor pixel 12 on the front surface 11a side of the first semiconductor substrate 11. The source of the transfer transistor TR is the high-concentration n-type layer 51, and the high-concentration n-type layer 51 provided for each sensor pixel 12 is electrically connected by the wire L2 to form the floating diffusion FD.

A back surface of the first substrate 10 opposite to the front surface 11a is a light incident surface. Therefore, the photodetector device 1 is a back-illuminated solid-state imaging device, and a color filter and an on-chip lens are provided on the back surface side serving as the light incident surface. For example, the color filter and the on-chip lens each are provided for each sensor pixel 12.

The first semiconductor substrate 11 of the first substrate 10 includes, for example, a silicon substrate. A p-type layer 53 (hereinafter, referred to as a p-well 53) that is a well layer is provided in a part of and near the front surface 11a of the first semiconductor substrate 11, and an n-type layer 54 forming the photodiode PD is provided in a region deeper than the p-well 53. The gate electrode TG of the transfer transistor TR extends from the front surface 11a of the first semiconductor substrate 11 to a depth at which the gate electrode penetrates the p-well 53 and reaches the n-type layer 54 serving as the photodiode PD. A reference potential (e.g., ground potential: 0 V) is supplied to the high-concentration p-type layer 52 serving as a contact portion of the p-well 53 via the wire L1, and a potential of the p-well 53 is set to the reference potential.

The first semiconductor substrate 11 is provided with a pixel isolation layer 55 that electrically isolates adjacent sensor pixels 12 from each other. The pixel isolation layer 55 has, for example, a deep trench isolation (DTI) structure and extends in the depth direction of the first semiconductor substrate 11. The pixel isolation layer 55 is made from, for example, a silicon oxide. Further, in the first semiconductor substrate 11, a p-type layer 56 and an n-type layer 57 are provided between the pixel isolation layer 55 and the photodiode PD (n-type layer 54). The p-type layer 56 is formed on the pixel isolation layer 55 side, and the n-type layer 57 is formed on the photodiode PD side.

An interlayer insulation film 58 is provided on the front surface 11a side of the first semiconductor substrate 11. The interlayer insulation film 58 is, for example, one of a silicon oxide film (SiO), a silicon nitride film (SiN), a silicon oxynitride film (SiON), or a silicon carbonitride film (SiCN), or a film in which two or more thereof are layered.

The second semiconductor substrate 21 of the second substrate 20 includes, for example, a silicon substrate. The second semiconductor substrate 21 has a front surface 21a facing the first substrate 10 and a back surface 21b located opposite to the front surface 21a. In FIG. 3, the front surface 21a is a lower surface, and the back surface 21b is an upper surface.

The second semiconductor substrate 21 includes, for example, a p-type layer 71 (hereinafter, referred to as a p-well 71) that is a well layer, and the amplifier transistor AMP, the selection transistor SEL, and the reset transistor RST are formed on the back surface 21b side of the second semiconductor substrate 21.

An element isolation layer 72 is formed between the amplifier transistor AMP and the reset transistor RST. A high-concentration p-type layer 73 that is a contact portion of the p-well 71 is formed between the selection transistor SEL and the reset transistor RST, and the element isolation layer 72 is also formed between the selection transistor SEL and the high-concentration p-type layer 73 and between the reset transistor RST and the high-concentration p-type layer 73. The element isolation layer 72 has, for example, a shallow trench isolation (STI) structure. The reference potential (e.g., ground potential: 0 V) is supplied to the high-concentration p-type layer 73 via the wire L1, and a potential of the p-well 71 is set to the reference potential.

The amplifier transistor AMP includes a gate electrode AG, a high-concentration n-type layer 74 as the drain, and a high-concentration n-type layer 75 (hereinafter, referred to as a source portion 75) as the source. The gate electrode AG of the amplifier transistor AMP has a structure in which a part thereof is embedded in the depth direction from a substrate surface (back surface 21b) of the second semiconductor substrate 21.

The reset transistor RST includes a gate electrode RG, a high-concentration n-type layer 76 (hereinafter, referred to as a drain portion 76) as the drain, and a high-concentration n-type layer 77 (hereinafter, referred to as a source portion 77) as the source. The selection transistor SEL includes a gate electrode SG, a high-concentration n-type layer 78 as the drain, and a high-concentration n-type layer 79 as the source.

The gate electrode AG of the amplifier transistor AMP is connected to the high-concentration n-type layer 51 provided for each sensor pixel 12 in the first semiconductor substrate 11 by the wire L2. Further, the gate electrode AG of the amplifier transistor AMP is also connected to the source portion 77 of the reset transistor RST by the wire L3. The high-concentration n-type layer 51 of each sensor pixel 12 including the wires L2 and L3 and the source portion 77 of the reset transistor RST form the floating diffusion FD.

The high-concentration n-type layer 74 serving as the drain of the amplifier transistor AMP and the drain portion 76 of the reset transistor RST are connected by the wire L4. A predetermined power supply voltage VDD is supplied to the high-concentration n-type layer 74 and the drain portion 76 via the wire L4.

The source portion 75 of the amplifier transistor AMP and the high-concentration n-type layer 78 serving as the drain of the selection transistor SEL are connected by the wire L5.

The gate electrode RG of the reset transistor RST is connected to the pixel drive line 23 via the wire L6, and a drive signal for controlling the reset transistor RST is supplied from the vertical drive circuit 33.

The gate electrode SG of the selection transistor SEL is connected to the pixel drive line 23 via the wire L7, and a drive signal for controlling the selection transistor SEL is supplied from the vertical drive circuit 33. The high-concentration n-type layer 79 serving as the source of the selection transistor SEL is connected to the vertical signal line 24 (FIG. 2) via the wire L8, and a pixel signal having a voltage corresponding to a charge held in the floating diffusion FD is output to the vertical signal line 24 via the wire L8.

The gate electrode TG of the transfer transistor TR is connected to the pixel drive line 23 via the wire L9, and a drive signal for controlling the transfer transistor TR is supplied from the vertical drive circuit 33.

The second substrate 20 includes an insulation film 81 that covers the front surface 21a, a part of the back surface 21b, and side surfaces of the second semiconductor substrate 21. The insulation film 81 is, for example, one of SiO, SiN, SiON, and SiCN, or a film in which two or more thereof are layered. The interlayer insulation film 58 of the first substrate 10 and the interlayer insulation film 81 of the second substrate 20 are bonded to each other to form an interlayer insulation film 82.

Any metal material can be selected as a material of the wires L1 to L9, and, for example, a portion extending in a layer direction of the first substrate 10 and the second substrate 20 can be made from tungsten (W), and a portion extending in a direction orthogonal to the layer direction (e.g., horizontal direction) can be made from copper (Cu) or a Cu alloy containing Cu as a main component.

### Comparative Example of First Embodiment

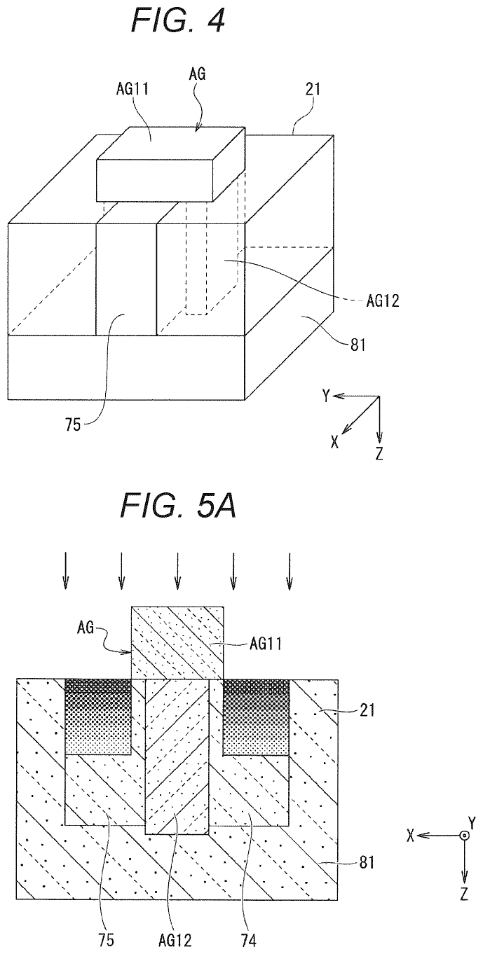

Meanwhile, in a pixel transistor such as the amplifier transistor AMP, as depicted in FIG. 4, ion implantation for forming the source portion 75 and the drain portion 74 (the back side of the sheet in FIG. 4) needs to be perpendicularly incident and thus is self-aligned with a top plate portion AG11 of the gate electrode AG, and is not self-aligned with a side wall portion AG12.

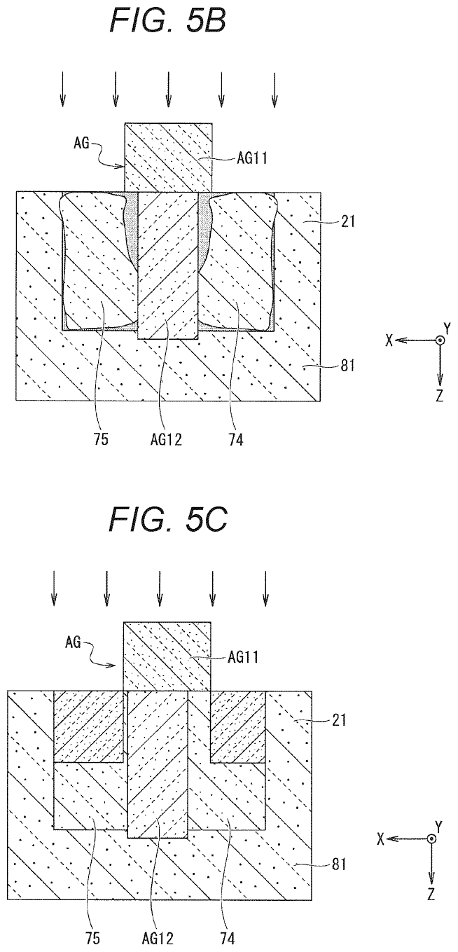

As depicted in FIG. 5A, the drain portions 74 and 75 are covered with a silicon oxide (SiO) of the second semiconductor substrate 21, and thus it is difficult to increase an effective gate width W in the depth direction (direction indicated by the arrow Z in FIG. 5A) of the second semiconductor substrate 21. Further, as depicted in FIG. 5B, when impurity implantation energy of the drain portion 74 and the source portion 75 is increased in order to use the entire fin as effectively as possible, diffusion occurs in the depth direction of the second semiconductor substrate 21, and short channel suppression becomes difficult. Furthermore, as depicted in FIG. 5C, in a case where the top plate portion AG11 and the side wall portion AG12 of the gate electrode AG are misaligned, the side wall portion AG12 is biased with respect to the drain portion 74 and the source portion 75, and the electric field becomes non-uniform.

### Solving Means of First Embodiment

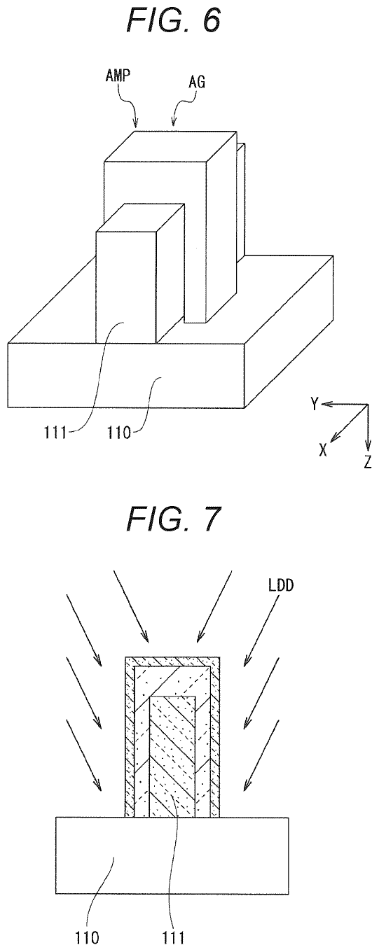

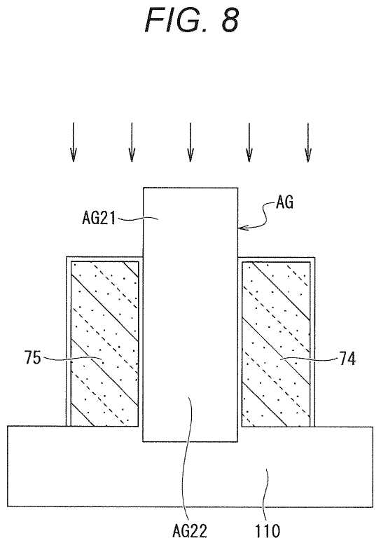

To solve the above problem, in the first embodiment of the present disclosure, as depicted in FIG. 6, a fin portion 111 serving as a diffusion layer region in which a channel is formed is formed on a substrate 110, and, for example, the gate electrode AG of the amplifier transistor AMP is formed to cover the fin portion 111. Then, as depicted in FIG. 7, ions are implanted obliquely (5 to 20 degrees) into the fin portion 111 to form the drain portion 74 and the source portion 75 as depicted in FIG. 8.

Therefore, a top plate portion AG21 and a side wall portion AG22 of the gate electrode AG of the amplifier transistor AMP have a self-aligned structure, and the side wall portion AG22, lightly doped drain (LDD), the drain portion 74, and the source portion 75 have a self-aligned structure.

### Effects of First Embodiment

As described above, according to the first embodiment, the drain portion 74 and the source portion 75 are formed to be self-aligned by exposing the top plate portion AG21 and the side wall portion AG22 of the gate electrode AG of the amplifier transistor AMP and implanting the impurities LDD obliquely into the side wall portion AG22 of the gate electrode AG. Thus, it is possible to achieve expansion of the effective gate width W in the depth direction of the second semiconductor substrate 21, suppression of variations in transistor characteristics, and short channel suppression.

### SECOND EMBODIMENT

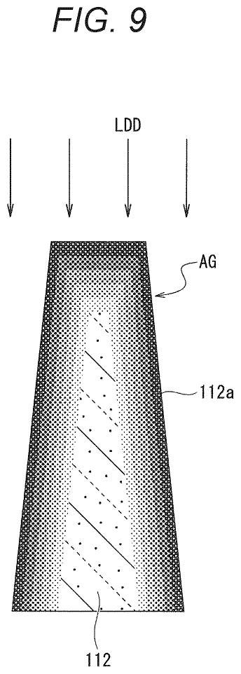

FIG. 9 is a cross-sectional view depicting a state of forming the drain portion 74 and the source portion 75 as a second embodiment of the present disclosure. As depicted in FIG. 9, a side wall portion 112a of a fin portion 112 is formed obliquely (70 to 85 degrees), and the gate electrode AG is formed, then ions are implanted vertically or obliquely to form the drain portion 74 and the source portion 75.

### Effects of Second Embodiment

As described above, according to the second embodiment, it is possible to obtain similar effects to those of the first embodiment described above.

### THIRD EMBODIMENT

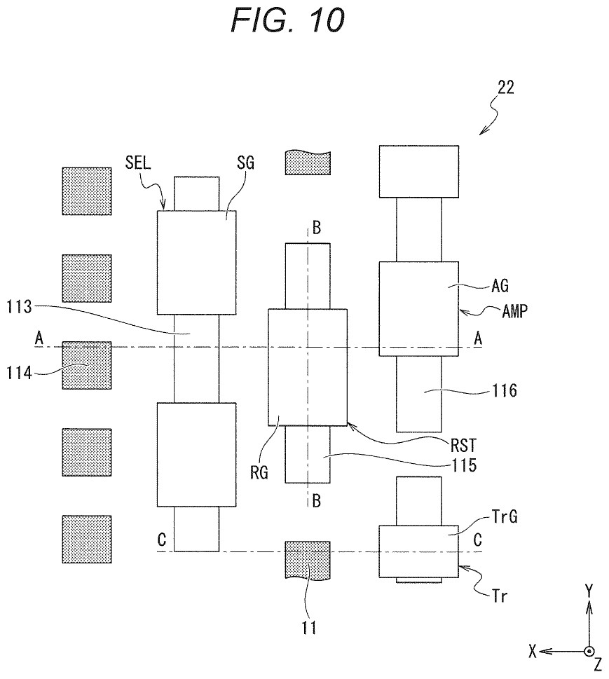

FIG. 10 is a plan view of the readout circuit 22 according to a third embodiment of the present disclosure. In the readout circuit 22, for example, the amplifier transistor AMP, the reset transistor RST, and the selection transistor SEL are arranged on the second semiconductor substrate 21 so as to have channels in the same direction (direction indicated by the arrow Y in FIG. 10).

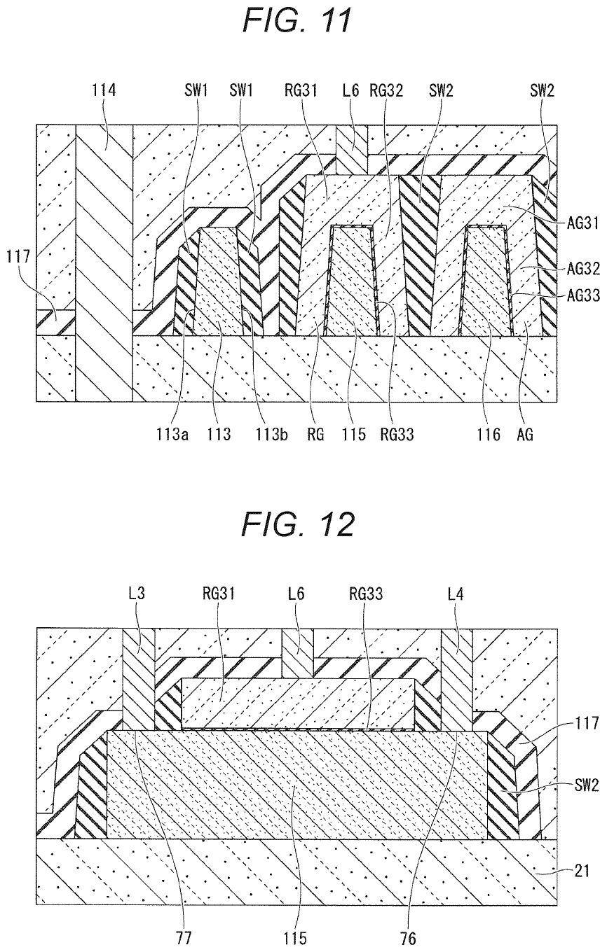

FIG. 11 schematically depicts a cross section taken along line A in FIG. 10. The line A is an imaginary line passing through the gate electrode AG of the amplifier transistor AMP, the gate electrode RG of the reset transistor RST, and a fin portion 113 serving as the drain of the selection transistor SEL. Further, the line A passes through a through contact 114 that connects the first substrate 10 and the second substrate 20.

The gate electrode RG of the reset transistor RST covers a fin portion 115. The gate electrode AG of the amplifier transistor AMP covers a fin portion 116. Side walls SW1 are provided on side wall portions 113a and 113b of the fin portion 113. Further, side walls SW2 are provided around the gate electrode RG of the reset transistor RST and around the gate electrode AG of the amplifier transistor AMP. The side walls SW1 and SW2 include, for example, an insulation film such as a silicon nitride film (SiN) or a silicon oxide film (SiO2).

Further, an etching stop layer (ESL) 117 is provided around the side walls SW1 and SW2, on an upper surface of the fin portion 113, on a top plate portion RG31 of the gate electrode RG of the reset transistor RST, and on a top plate portion AG31 of the gate electrode AG of the amplifier transistor AMP. The ESL 117 is layered on the lower (front surface) side of the second semiconductor substrate 21 that is a silicon layer and functions as a stopper for a contact on the gate or an active region.

By the way, the top plate portion RG31 of the gate electrode RG has a larger film thickness than the side wall portion RG32. Note that the film thickness of the top plate portion RG31 is 50 to 200 nm, and the film thickness of the side wall portion RG32 is 20 to 150 nm. Further, the film thickness of the top plate portion RG31 of the gate electrode RG is larger than a half value of a space between the fin portion 115 and the fin portion 116 and a half value of a space between the fin portion 113 and the fin portion 115. In this way, the space between the fin portion 115 and the fin portion 116 and the space between the fin portion 113 and the fin portion 115 can be filled with a gate electrode material. This makes it possible to simplify a mask structure when a gate electrode pattern is formed.

Further, a gate oxide film RG33 is formed between the gate electrode RG and the fin portion 115. A gate oxide film AG33 is also formed between the gate electrode AG and the fin portion 116.

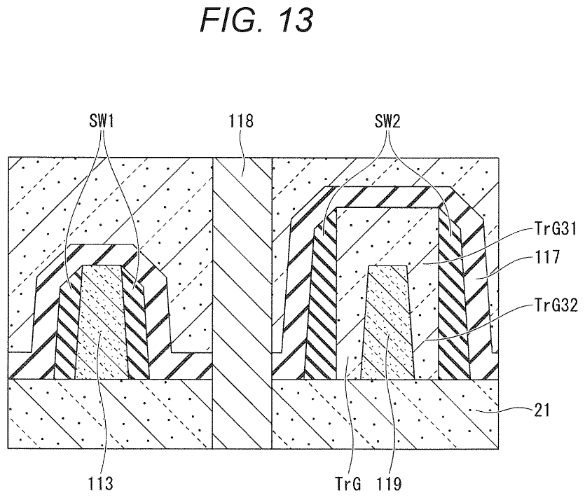

FIG. 12 schematically depicts a cross section taken along line B in FIG. 10. The line B is an imaginary line passing through the gate electrode RG of the reset transistor RST and the fin portion 115. The wire L6 is connected to the gate electrode RG. The wire L3 is connected to the source portion 77 connected to the fin portion 115. The wire L4 is connected to the drain portion 76 connected to the fin portion 115.

FIG. 13 schematically depicts a cross section taken along line C in FIG. 10. The line C is an imaginary line passing through the fin portion 113, a through contact 118, and a gate electrode TrG of another pixel transistor Tr. The gate electrode TrG of the pixel transistor Tr covers a fin portion 119. Further, the side wall SW2 is provided around the gate electrode TrG of the pixel transistor Tr.

Furthermore, the ESL 117 is provided around the side walls SW1 and SW2, on the upper surface of the fin portion 113, and on a top plate portion TrG31 of the gate electrode TrG of the pixel transistor Tr. The ESL 117 functions as a stopper for a contact on the gate or the active region.

### Method of Manufacturing Photodetector Device

Next, a method of manufacturing the photodetector device 1 in FIG. 1 will be described. Note that the photodetector device 1 is manufactured by using various devices such as a film forming device (including a chemical vapor deposition (CVD) device and a sputtering device), an ion implantation device, a heat treatment device, an etching device, a chemical mechanical polishing (CMP) device, and a bonding device. Hereinafter, those devices will be collectively referred to as a manufacturing device.

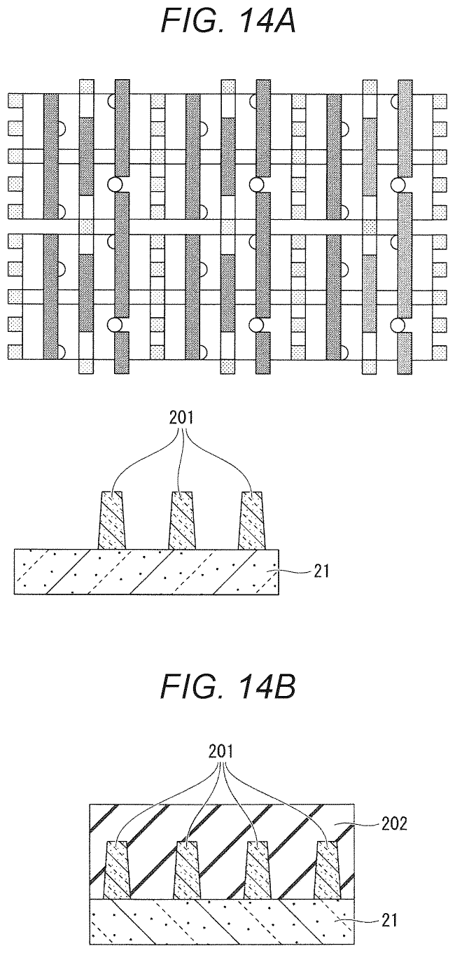

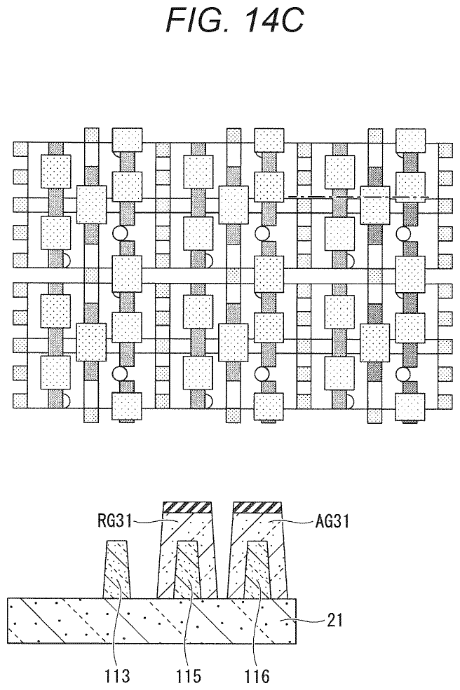

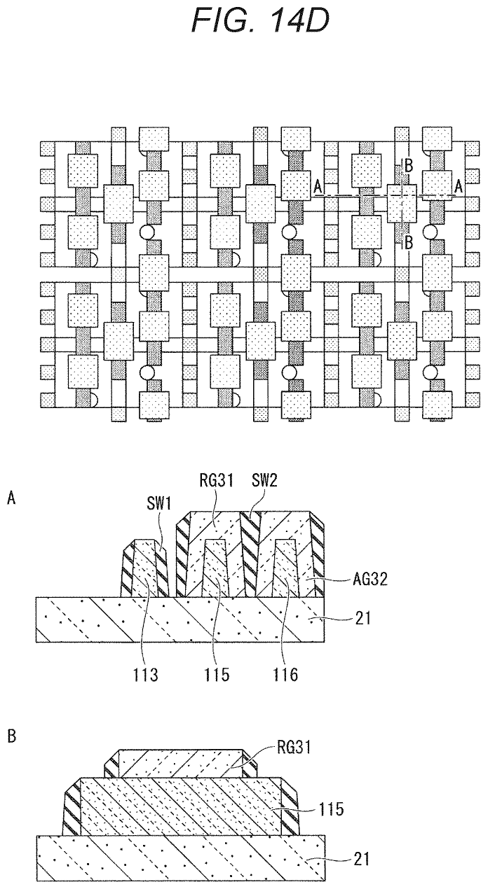

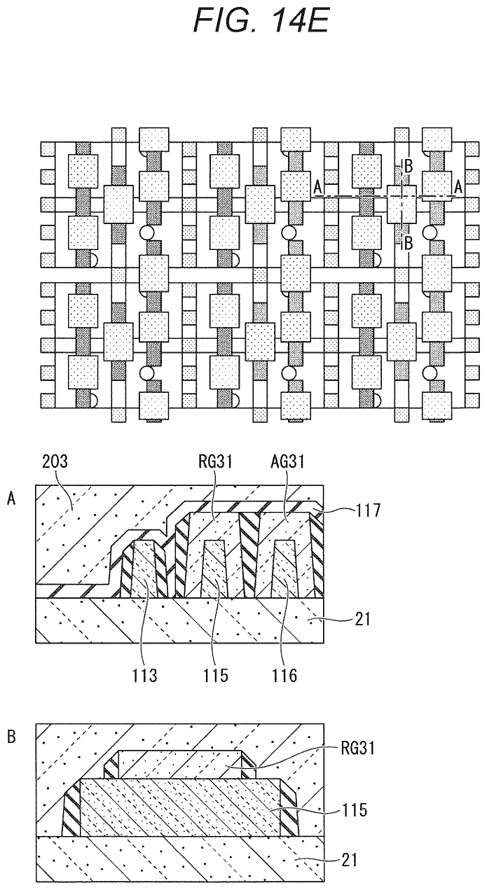

FIGS. 14A to 14E are cross-sectional views depicting the method of manufacturing the photodetector device 1 according to the third embodiment of the present disclosure in order of steps. First, the manufacturing device manufactures the first substrate 10 including the floating diffusion FD and the photodiode PD and bonds the second substrate 20 onto the interlayer insulation film 58 of the first substrate 10.

Next, as depicted in FIG. 14A, the manufacturing device forms a fin mask pattern on the second semiconductor substrate 21 of the second substrate 20 and dry-etches the upper surface of the semiconductor substrate 21 to form fin portions 201.

Next, as depicted in FIG. 14B, the manufacturing device forms a gate oxide film around the fin portions 201 and further forms a gate electrode material 202. Then, the manufacturing device forms a gate mask pattern and forms the gate electrodes RG31 and AG31 depicted in FIG. 14C by dry etching. Thereafter, ion implantation (LDD) is performed on each of the fin portions 113, 115, and 116.

Next, as depicted in FIG. 14D, the manufacturing device forms a side wall material around the fin portion 113, around the gate electrode RG of the reset transistor RST, and around the gate electrode AG of the amplifier transistor AMP and forms the side walls SW1 and SW2 by dry etching.

Next, as depicted in FIG. 14E, after activation by annealing (ANL) processing, the manufacturing device forms the ESL 117, further forms a pre metal dielectric (PMD) 203, and planarizes the PMD 203. The ANL processing is, for example, processing in which heat treatment is performed in an N2 atmosphere or vacuum at atmospheric pressure by an annealing device such as a hot plate or an RTA.

### Effects of Third Embodiment

As described above, according to the third embodiment, for example, the amplifier transistor AMP, the reset transistor RST, and the selection transistor SEL are arranged on the second semiconductor substrate 21 so as to have channels in the same direction (direction indicated by the arrow Y in FIG. 10). This makes it possible to reduce the number of manufacturing steps because no mask is required at the time of LDD tilt implantation.

Further, according to the third embodiment, in a case where the fin portion 113, the fin portion 115, and the fin portion 116 are arranged at equal intervals, a lithography line width is narrowed, which is advantageous for miniaturization.

Further, according to the third embodiment, when the film thickness of the top plate portion RG31 of the gate electrode RG is larger than the film thickness of the side wall portion RG32, it is possible to prevent penetration at the time of the LDD tilt implantation and to achieve miniaturization. Further, when the film thickness of the top plate portion RG31 of the gate electrode RG is larger than the half value of the space between the fin portion 115 and the fin portion 116 and the half value of the space between the fin portion 113 and the fin portion 115, the photodetector device 1 can be easily manufactured.

### FOURTH EMBODIMENT

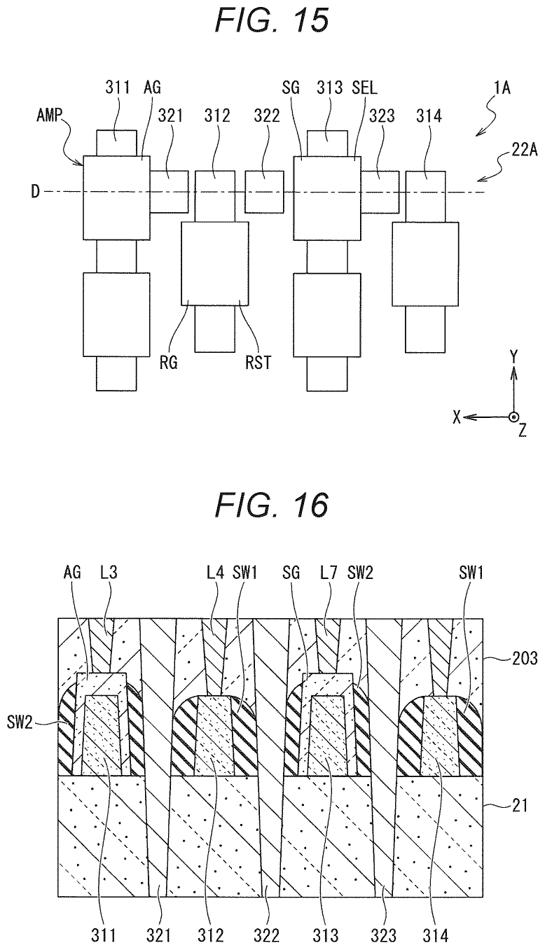

FIG. 15 is a plan view of a readout circuit 22A in a photodetector device 1A according to a fourth embodiment of the present disclosure. In the readout circuit 22A, for example, the amplifier transistor AMP, the reset transistor RST, and the selection transistor SEL are arranged on the second semiconductor substrate 21 so as to have channels in the same direction (direction indicated by the arrow Y in FIG. 15).

FIG. 16 schematically depicts a cross section taken along line D in FIG. 15. The line D is an imaginary line passing through the gate electrode AG of the amplifier transistor AMP, a fin portion 312 serving as the source of the reset transistor RST, the gate electrode SG of the selection transistor SEL, and a fin portion 14. Further, the line D passes through contacts 321, 322, and 323 that connect the first substrate 10 and the second substrate 20.

The gate electrode AG of the amplifier transistor AMP covers a fin portion 311. The gate electrode SG of the selection transistor SEL covers a fin portion 313. The fin portions 311, 312, 313, and 314 are arranged at equal intervals. The side walls SW1 are provided on side wall portions of the fin portions 312 and 314. Further, the side walls SW2 are provided around the gate electrode AG of the amplifier transistor AMP and around the gate electrode SG of the selection transistor SEL.

### Comparative Example of Fourth Embodiment

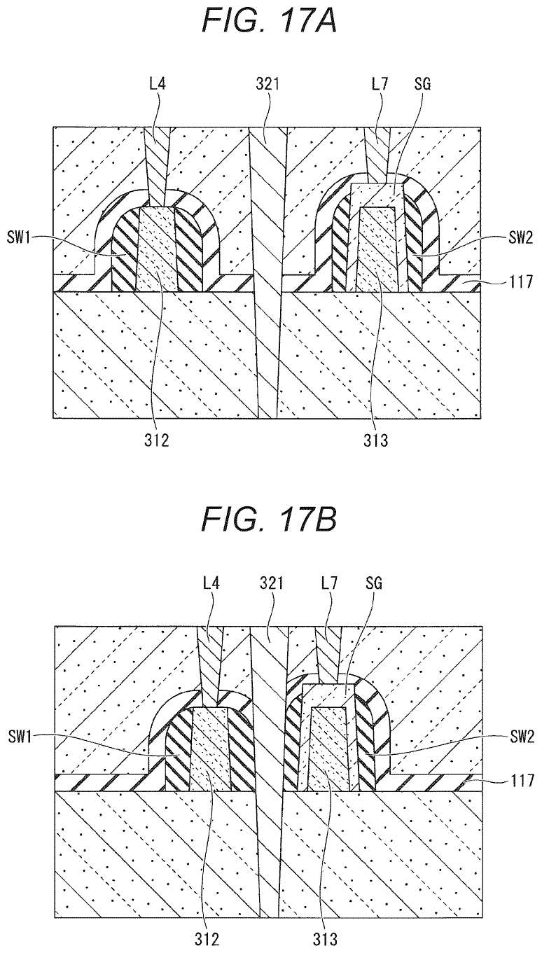

FIG. 17A schematically depicts a cross section of the readout circuit 22 as a comparative example of the fourth embodiment. Note that, in FIG. 17A, the same portions as those in FIG. 16 described above are denoted by the same reference signs, and detailed explanation thereof is omitted.

In FIG. 17A, for example, the ESL 117 is provided around the side walls SW1 and SW2, on an upper surface of the fin portion 312, and on a top plate portion of the gate electrode SG of the selection transistor SEL. Here, in a case where the layout is reduced, as depicted in FIG. 17B, the ESL 117 is formed as a thick film between the fin portion 312 and the fin portion 313. Therefore, when the through contact 321 is formed, the through contact 321 may fail to penetrate.

### Solving Means of Fourth Embodiment

To solve the above problem, in the fourth embodiment of the present disclosure, as depicted in FIG. 18, the ESL 117 is eliminated, and the through contact 321 is in direct contact with the side walls SW1 and SW2.

### Manufacturing Method

Next, a method of manufacturing the photodetector device 1A will be described. Note that the photodetector device 1A is manufactured by using various devices such as a film forming device (including a chemical vapor deposition (CVD) device and a sputtering device), an ion implantation device, a heat treatment device, an etching device, a chemical mechanical polishing (CMP) device, and a bonding device. Hereinafter, those devices will be collectively referred to as a manufacturing device.

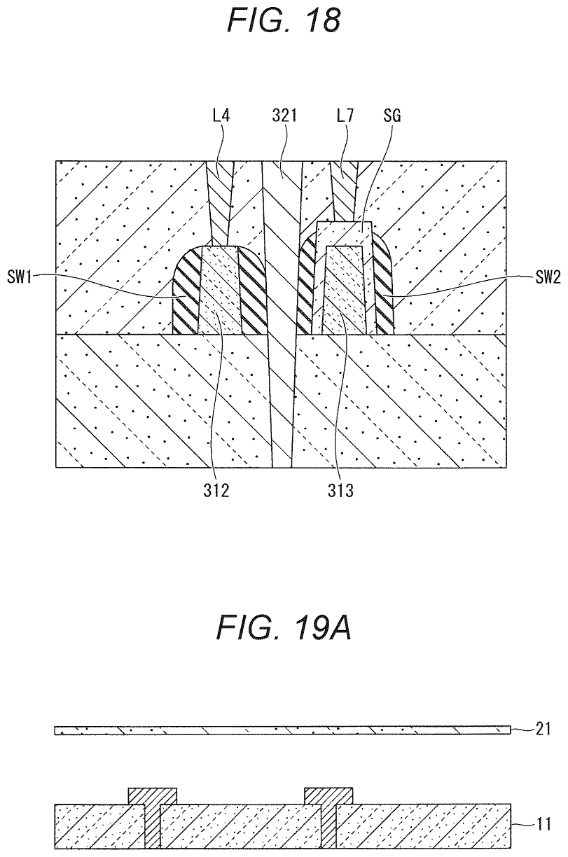

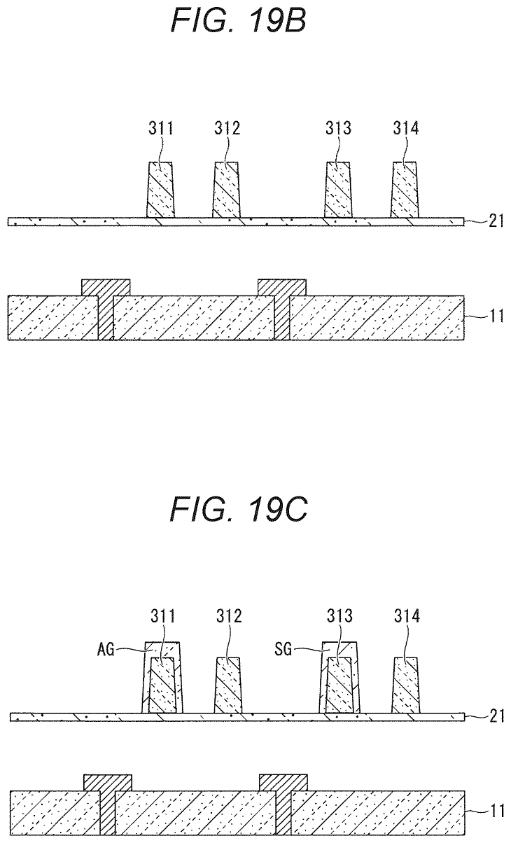

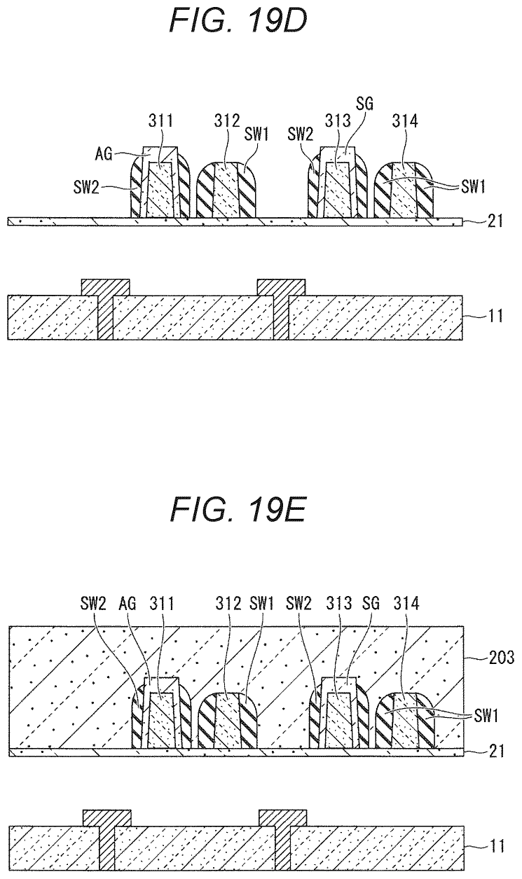

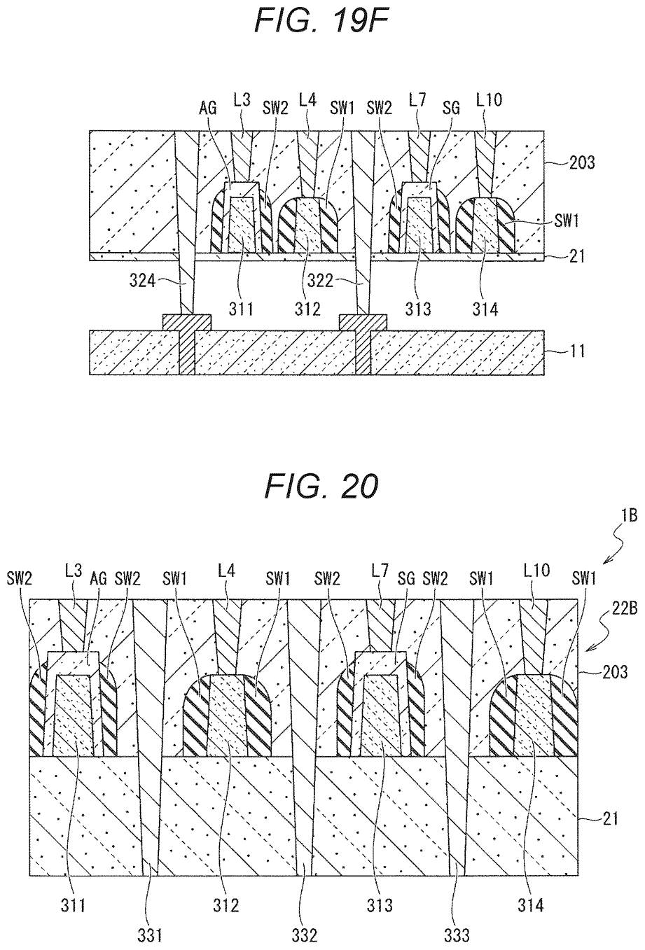

FIGS. 19A to 19F are cross-sectional views depicting the method of manufacturing the photodetector device 1A according to the fourth embodiment of the present disclosure in order of steps. First, as depicted in FIG. 19A, the first semiconductor substrate 11 is prepared, and a 1F portion is formed. In the 1F, the photodiode PD, the floating diffusion FD, the transfer transistor TR, and the like are formed.

Next, as depicted in FIG. 19B, the second semiconductor substrate 21 of 2F is bonded and is thinned, and silicon is processed to form the fin portions 311, 312, 313, and 314.

Next, as depicted in FIG. 19C, the gate electrode AG is formed on the fin portion 311, and the gate electrode SG is formed on the fin portion 313. As depicted in FIG. 19D, the side wall SW1 is formed on the side wall portion of each of the fin portions 312 and 314, and the side wall SW1 is formed on the side wall portion of each of the gate electrodes AG and SG.

Next, as depicted in FIG. 19E, the single-layer PMD 203 is formed around the side walls SW1 and SW2, on the upper surfaces of the fin portions 312 and 314, on the top plate portion of the gate electrode AG of the amplifier transistor AMP, and on the top plate portion of the gate electrode SG of the selection transistor SEL. As depicted in FIG. 19F, the through contacts 322 and 324 penetrating the second semiconductor substrate 21 and the PMD 203 are formed, and the first semiconductor substrate 11 of the 1F and the second semiconductor substrate 21 of the 2F are connected by the through contacts 322 and 324. At the same time, the wire L3 serving as CS is formed on the top plate portion of the gate electrode AG, the wire L4 is formed on the upper surface of the fin portion 312, the wire L7 is formed on the top plate portion of the gate electrode SG, and the wire L10 is formed on the upper surface of the fin portion 314.

### Effects of Fourth Embodiment

As described above, according to the fourth embodiment, when the ESL 117 of the second substrate portion 20 of the 2F is eliminated, and the through contacts 321, 322, and 323 are in contact with the side walls SW1 and SW2, the side walls SW1 and SW2 function as self-aligned contacts of the through contacts 321, 322, and 323. This makes it possible to reduce a distance between the field-effect transistors and to reduce the layout. Further, because there is no ESL 117, it is possible to prevent a failure of penetration of the through contacts 321, 322, and 323. Furthermore, because the fin portions 311, 312, and 313 are n-type, and there is no p-type well, junction leakage due to CS processing does not occur even without the ESL 117.

### FIFTH EMBODIMENT

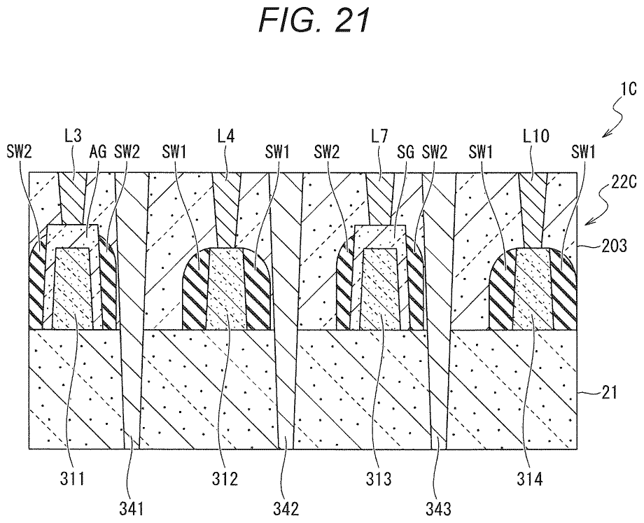

FIG. 20 schematically depicts a cross section of a readout circuit 22B of a photodetector device 1B according to a fifth embodiment of the present disclosure. Note that, in FIG. 20, the same portions as those in FIG. 16 described above are denoted by the same reference signs, and detailed description thereof is omitted.

In the fifth embodiment of the present disclosure, the ESL 117 is eliminated, and through contacts 331, 332, and 333 are not in contact with the side walls SW1 and SW2.

### Effects of Fifth Embodiment

As described above, according to the fifth embodiment, it is possible to further improve a failure of penetration of the through contacts 331, 332, and 333.

### SIXTH EMBODIMENT

FIG. 21 schematically depicts a cross section of a readout circuit 22C of a photodetector device 1C according to a sixth embodiment of the present disclosure. Note that, in FIG. 21, the same portions as those in FIG. 16 described above are denoted by the same reference signs, and detailed description thereof is omitted.

In the sixth embodiment of the present disclosure, the ESL 117 is eliminated, and through contacts 341, 342, and 343 are in contact with only one side of the side wall SW1 or SW2.

### Effects of Sixth Embodiment

As described above, according to the sixth embodiment, it is possible to reduce the distance between the field-effect transistors and to further improve a failure of penetration of the through contacts 341, 342, and 343.

### SEVENTH EMBODIMENT

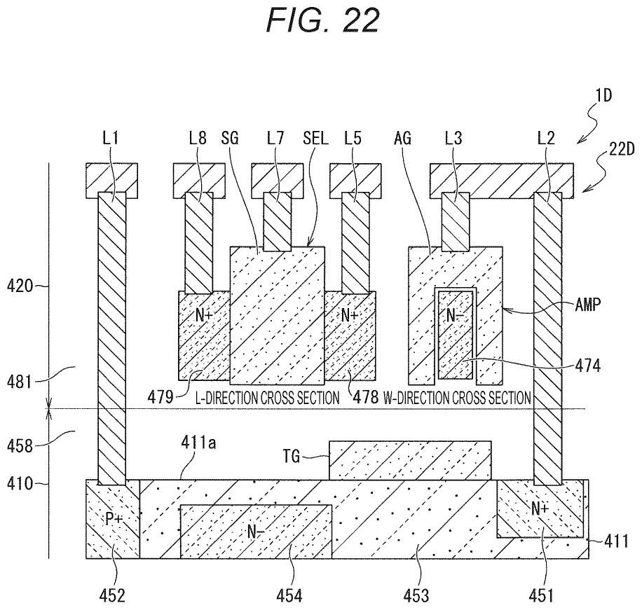

FIG. 22 schematically depicts a cross section of a readout circuit 22C of a photodetector device 1D according to a seventh embodiment of the present disclosure. Note that, in FIG. 21, the same portions as those in FIG. 16 described above are denoted by the same reference signs, and detailed description thereof is omitted.

In the seventh embodiment of the present disclosure, a high-concentration n-type layer (n+-type diffusion layer) 451 that is a part of the floating diffusion FD, the gate electrode TG of the transfer transistor TR, and a high-concentration p-type layer (p-type diffusion layer) 452 are arranged side by side in the lateral direction.

As depicted in FIG. 22, in the photodetector device 1D, a first substrate 410 and a second substrate 420 are layered to form a layered body. The first substrate 410 includes a first semiconductor substrate 411, and a second substrate 420 is layered on a front surface 411a side of the first semiconductor substrate 411. That is, the second substrate 420 is face-to-back bonded to the first substrate 410.

The transfer transistor TR is provided for each sensor pixel 12 on the front surface 411a side of the first semiconductor substrate 411. The source of the transfer transistor TR is the high-concentration n-type layer 451, and the high-concentration n-type layer 451 provided for each sensor pixel 12 is electrically connected by the wire L2 to form the floating diffusion FD.

A back surface of the first substrate 410 opposite to the front surface 411a is a light incident surface. Therefore, the photodetector device 1D is a back-illuminated solid-state imaging device, and a color filter and an on-chip lens are provided on the back surface side serving as the light incident surface. For example, the color filter and the on-chip lens each are provided for each sensor pixel 12.

The first semiconductor substrate 411 of the first substrate 410 includes, for example, a silicon substrate. An n-type layer 453 is provided on a part of and near the front surface 411a of the first semiconductor substrate 411, and an n—type layer 454 forming the photodiode PD is provided in a region deeper than the n-type layer 453. The reference potential (e.g., ground potential: 0 V) is supplied to the high-concentration p-type layer 452 serving as a contact portion via the wire L1, and a potential of the n-type layer 453 is set to the reference potential.

An insulation film 458 is provided on the front surface 411a side of the first semiconductor substrate 411. The insulation film 458 is, for example, one of a silicon oxide film (SiO), a silicon nitride film (SiN), a silicon oxynitride film (SiON), or a silicon carbonitride film (SiCN), or a film in which two or more thereof are layered.

For example, the amplifier transistor AMP and the selection transistor SEL are formed on the second substrate 420. Further, an insulation film 481 is provided on a back surface side of the second substrate 420.

The amplifier transistor AMP includes the gate electrode AG, a high-concentration n-type layer (not depicted) as a drain portion, and a high-concentration n-type layer (not depicted) as a source portion. The gate electrode AG of the amplifier transistor AMP covers a fin portion 474 of a low-concentration n-type layer forming a channel connected to the drain portion and the source portion. The gate electrode AG of the amplifier transistor AMP is connected to the high-concentration n-type layer 51 of each sensor pixel 12 by the wire L3 and the wire L2.

The gate electrode SG of the selection transistor SEL is connected to the pixel drive line 23 via the wire L7, and a drive signal for controlling the selection transistor SEL is supplied from the vertical drive circuit 33. A high-concentration n-type layer 479 (hereinafter, referred to as a source portion 479) serving as the source of the selection transistor SEL is connected to the vertical signal line 24 (FIG. 2) via the wire L8, and a pixel signal having a voltage corresponding to a charge held in the floating diffusion FD is output to the vertical signal line 24 via the wire L8. A high-concentration n-type layer 478 (hereinafter, referred to as the drain portion 478) serving as the drain of the selection transistor SEL is connected to the source portion of the amplifier transistor AMP via the wire L5.

A bottom portion of the gate electrode AG of the amplifier transistor AMP is deeper than a bottom portion of the fin portion 474. Further, a bottom portion of the gate electrode SG of the selection transistor SEL is deeper than bottom portions of the drain portion 478 and the source portion 479.

### Comparative Example of Seventh Embodiment

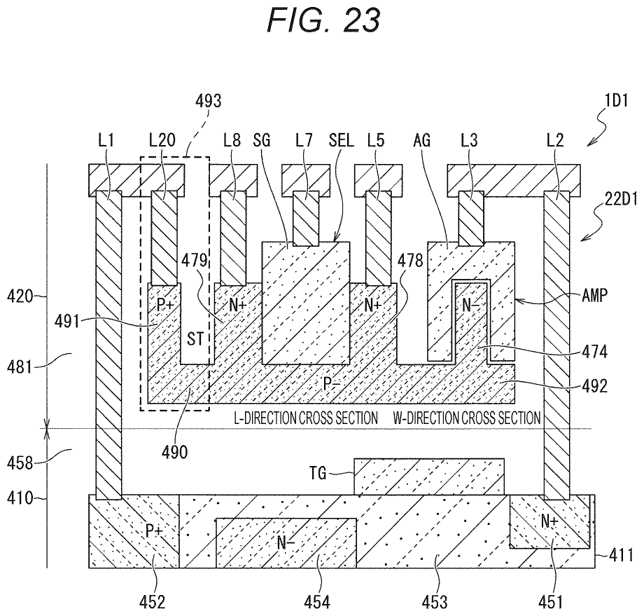

FIG. 23 schematically depicts a cross section of a readout circuit 22D1 of a photodetector device 1D1 as a comparative example of the seventh embodiment. Note that, in FIG. 23, the same portions as those in FIG. 22 described above are denoted by the same reference signs, and detailed description thereof is omitted.

In the comparative example of the seventh embodiment, in a case where a well is provided in the second substrate 420 of the 2F, it is necessary to provide a region for tapping the well, that is, a well tap portion 490 and STI 493 that isolates the well tap portion 490 and other active regions. In the well tap portion 490, a high-concentration p-type layer 491 for connecting to a wire L20 and a low-concentration p-type layer 492 are formed.

When the well tap portion 490 is formed, the limit of reduction in size is determined depending on a minimum area of lithography. Further, also regarding the STI 493, the limit of reduction in size is determined depending on a lithography pattern, a fine processing technique such as dry etching, and an insulation film forming technique for embedding the inside of the STI 493. It is necessary to lay out the 2F portion in consideration of those relationships. In other words, an effective area of the 2F is lost due to the presence of the well tap portion 490 and the STI 493.

### Solving Means of Seventh Embodiment

To solve the above problem, in the seventh embodiment of the present disclosure, the 2F portion has only a single n-type. The pixel transistor of the 2F having such a configuration does not include a well, and thus it is unnecessary to arrange the well tap portion 490 and the STI 493 therearound. As a result, the problem of the decrease in the area efficiency of the 2F can be solved.

### Effects of Seventh Embodiment

As described above, according to the seventh embodiment, the pixel transistors such as the amplifier transistor AMP and the selection transistor SEL of the 2F do not include a well that is a p-type region, and thus it is unnecessary to arrange the well tap portion 490 and the STI 493 therearound. As a result, it is possible to solve the problem of the decrease in the area efficiency of the second substrate 420 of the 2F, and, by reducing a surplus portion caused by this, it is possible to reduce the number of pixels of the photodetector device ID. Further, it is also possible to improve the characteristics by using the surplus portion to increase the number of field-effect transistors or the gate length L and the gate width W of the field-effect transistors.

### EIGHTH EMBODIMENT

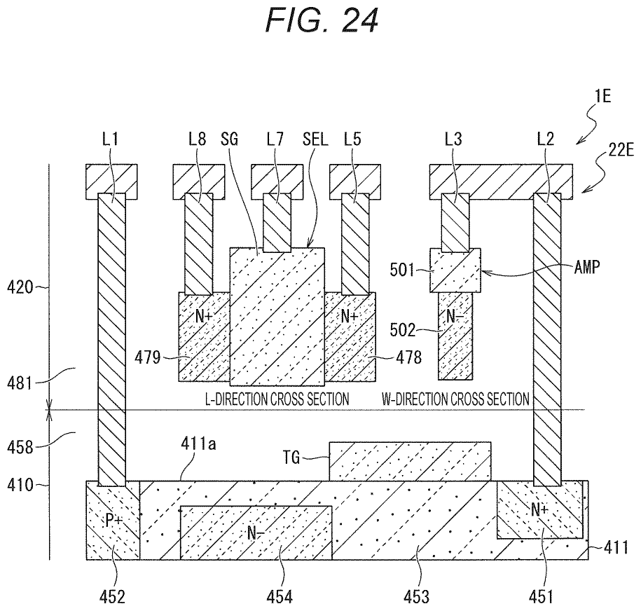

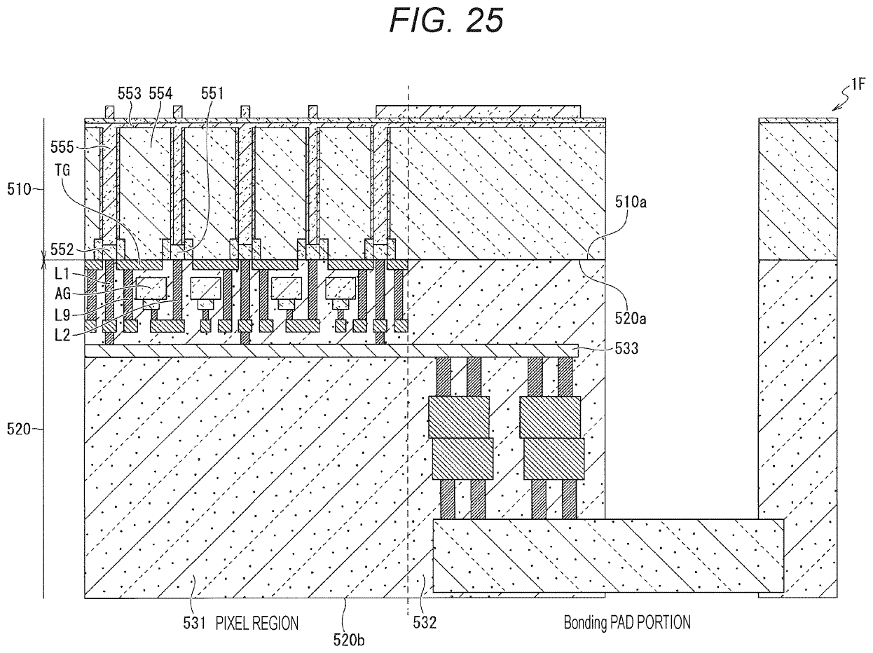

FIG. 24 schematically depicts a cross section of a readout circuit 22E of a photodetector device 1E according to an eighth embodiment of the present disclosure. Note that, in FIG. 24, the same portions as those in FIG. 22 described above are denoted by the same reference signs, and detailed description thereof is omitted.

In the eighth embodiment of the present disclosure, the amplifier transistor AMP is a planar (fully-depleted) amplifier transistor AMP in which the gate electrode 501 is formed only in a horizontal portion (from the back side to the front side of the sheet in FIG. 24). In other words, the gate electrode 501 does not have a vertical portion and is provided to face a diffusion layer 502.

### Effects of Eighth Embodiment

As described above, according to the eighth embodiment, the amplifier transistor AMP provided in the second substrate 420 of the 2F may be a fin or a planar or may be appropriately selected.

### NINTH EMBODIMENT

FIG. 25 schematically depicts a cross section of a photodetector device 1F according to a ninth embodiment of the present disclosure.

As depicted in FIG. 25, in the photodetector device 1F, a first substrate 510 and a second substrate 520 are layered to form a layered body. The second substrate 520 is layered on a front surface 510a side of the first substrate 510. That is, the second substrate 520 is face-to-back bonded to the first substrate 510. Further, the first substrate 510 and the second substrate 520 are provided with a pixel region 531 in which the photodiodes PD, the floating diffusions FD, and the pixel transistors are provided and a bonding pad portion 532 that can be connected to, for example, an external device and to which a power supply potential is supplied from the external device.

The transfer transistor TR is provided for each sensor pixel 12 on the front surface 510a side of the first substrate 510. The source of the transfer transistor TR is the high-concentration n-type layer 551, and the high-concentration n-type layer 551 provided for each sensor pixel 12 is electrically connected by the wire L2 to form the floating diffusion FD.

A back surface of the first substrate 510 opposite to the front surface 510a is a light incident surface. Therefore, the photodetector device 1F is a back-illuminated solid-state imaging device, and a color filter and an on-chip lens are provided on the back surface side serving as the light incident surface. For example, the color filter and the on-chip lens each are provided for each sensor pixel 12.

The first substrate 510 includes, for example, a silicon substrate. A high-concentration p-type layer 552 is provided on a part of or near the front surface 510a of the first substrate 510. An n-type layer 554 forming the photodiode PD is provided in a region on the back surface side of the first substrate 510. The reference potential (e.g., ground potential: 0 V) is supplied to the high-concentration p-type layer 552 via the wire L1.

The first substrate 510 is provided with a pixel isolation layer 555 that electrically isolates adjacent sensor pixels 12, i.e., the n-type layers 554 from each other. The pixel isolation layer 555 has, for example, a deep trench isolation (DTI) structure and extends in the depth direction of the first substrate 510. The pixel isolation layer 555 is made from, for example, a silicon oxide. Further, in the first substrate 510, a p-type layer 553 is formed on a back surface side of the n-type layer 554.

The second substrate 520 includes, for example, a silicon substrate. The second substrate 520 has a front surface 520a facing the first substrate 510 and a back surface 520b located opposite to the front surface 520a.

The second substrate 520 includes, for example, an n-type layer, and the pixel transistors such as the amplifier transistor AMP and the selection transistor SEL are formed on the back surface 520b side of the second semiconductor substrate 21.

The gate electrode AG of the amplifier transistor AMP is connected to the high-concentration n-type layer 551 provided for each sensor pixel 12 in the first substrate 510 by the wire L2. The high-concentration n-type layer 551 of each sensor pixel 12 and the high-concentration n-type layer serving as the source of the reset transistor RST form the floating diffusion FD.

In the ninth embodiment of the present disclosure, the reference potential (e.g., ground potential: 0 V) to be supplied to the high-concentration p-type layer 552 is supplied from the bonding pad portion 532 via the wire L1 and a conductive material 533. Further, a contact via is used for the wire L1. That is, the wire L1 connected to the high-concentration p-type layer 552 penetrates the second substrate 520 and is routed from the pixel region 531 to the bonding pad portion 532 via the conductive material 533. Note that the contact via is made from tungsten (W) or the like, and the conductive material 533 is made from aluminum (Al), copper (Cu), or the like.

### Effects of Ninth Embodiment

As described above, according to the ninth embodiment, it is possible to obtain the similar effects to those of the seventh embodiment described above and to simplify a wiring structure.

### TENTH EMBODIMENT

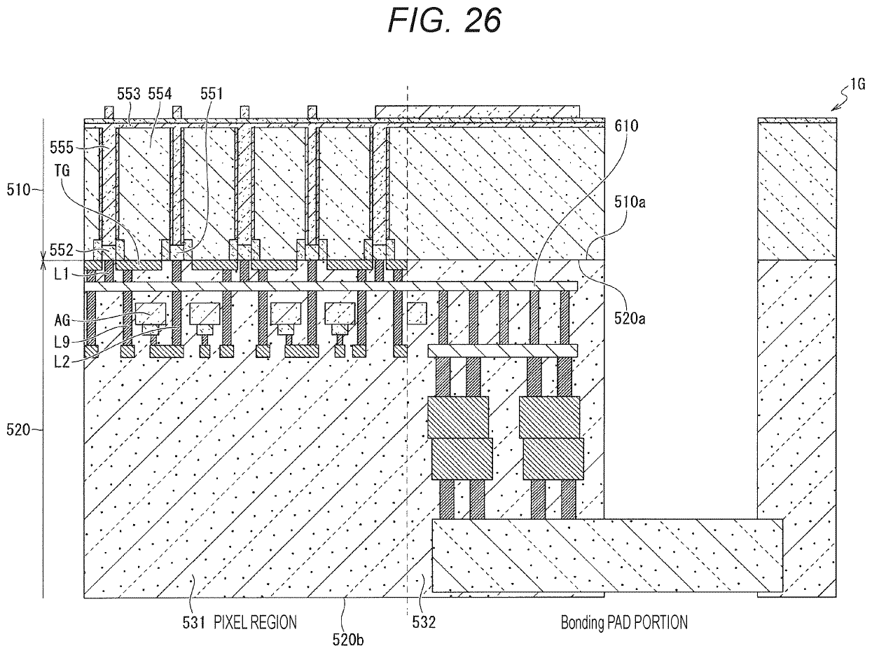

FIG. 26 schematically depicts a cross section of a photodetector device 1G according to a tenth embodiment of the present disclosure. Note that, in FIG. 26, the same portions as those in FIG. 25 described above are denoted by the same reference signs, and detailed description thereof is omitted.

In the tenth embodiment of the present disclosure, the reference potential (e.g., ground potential: 0 V) to be supplied to the high-concentration p-type layer 552 is supplied from the bonding pad portion 532 via the wire L1 and a conductive material 610. Here, the wire L1 connected to the high-concentration p-type layer 552 does not penetrate the second substrate 520 and is routed from the pixel region 531 to the bonding pad portion 532 via the conductive material 610. Note that the wire L1 and the conductive material 533 are made from a high heat resistant material such as doped poly Si, doped amorphous Si, W, or Ru. The temperature is, for example, a furnace of 700° C. or higher or an RTP of 1000° C. or higher.

### Effects of Tenth Embodiment

As described above, according to the tenth embodiment, it is possible to obtain the similar effects to those of the ninth embodiment described above and to simplify manufacturing steps and the wiring structure.

### ELEVENTH EMBODIMENT

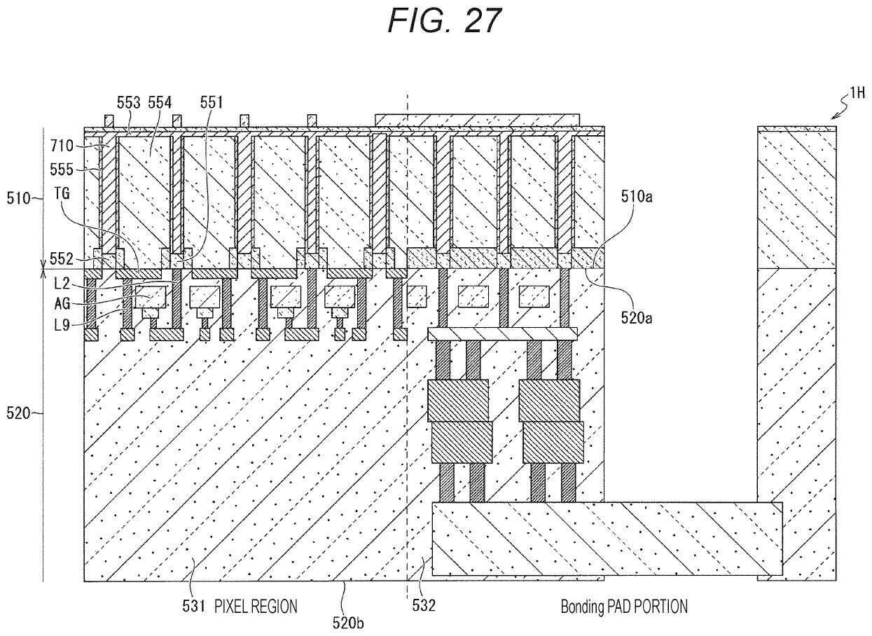

FIG. 27 schematically depicts a cross section of a photodetector device 1H according to an eleventh embodiment of the present disclosure. Note that, in FIG. 27, the same portions as those in FIG. 25 described above are denoted by the same reference signs, and detailed description thereof is omitted.

In the eleventh embodiment of the present disclosure, a conductive material 710 is embedded in each pixel isolation layer 555 of the first substrate 510. The reference potential (e.g., ground potential: 0 V) to be supplied to the high-concentration p-type layer 552 is supplied from the bonding pad portion 532 via the conductive material 710. Further, the bonding pad portion 532 is also provided with the conductive material 710. The conductive material 710 is aluminum (Al), copper (Cu (Qe increases due to high reflection)), ITO (Qe increases due to low absorption), doped poly Si, doped amorphous Si, or the like.

### Effects of Eleventh Embodiment

As described above, according to the eleventh embodiment, it is possible to obtain the similar effects to those of the ninth embodiment described above, and, because the reference potential is supplied from the bonding pad portion 532 to the high-concentration p-type layer 552 of the first substrate 510 by using the conductive material 710 embedded in the pixel isolation layer 555, it is possible to further simplify the manufacturing steps and the wiring structure.

### TWELFTH EMBODIMENT

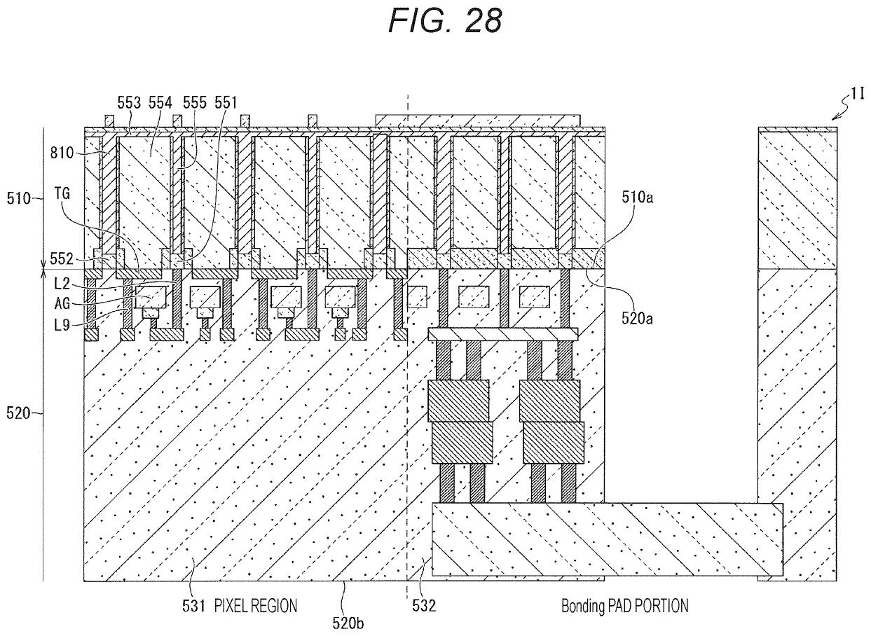

FIG. 28 schematically depicts a cross section of a photodetector device 1I according to a twelfth embodiment of the present disclosure. Note that, in FIG. 28, the same portions as those in FIG. 25 described above are denoted by the same reference signs, and detailed description thereof is omitted.

In the twelfth embodiment of the present disclosure, a through contact 810 connected to the high-concentration p-type layer 552 penetrates the n-type layer 554 of the first substrate 510. The reference potential (e.g., ground potential: 0 V) to be supplied to the high-concentration p-type layer 552 is supplied from the bonding pad portion 532 through the through contact 810 via a conductive material or the like that is formed on the light incident surface of the first substrate 510 and is different from that provided inside the pixel isolation layer 555.

### Effects of Twelfth Embodiment

As described above, according to the twelfth embodiment, it is possible to obtain similar effects to those of the eleventh embodiment described above.

### Other Embodiments

The present technology has been described as above according to the first to twelfth embodiments, but it should not be understood that the description and drawings forming a part of this disclosure limit the present technology. It will be apparent to those skilled in the art that various alternative embodiments, examples, and operation techniques can be included in the present technology when understanding the spirit of the technical content disclosed in the first to twelfth embodiments described above. Furthermore, the configurations disclosed in the first to twelfth embodiments can be appropriately combined within a range in which no contradiction occurs. For example, configurations disclosed in a plurality of different embodiments may be combined, or configurations disclosed in a plurality of different modifications of the same embodiment may be combined.

### Application Example to Electronic Apparatus

The photodetector device described above can be applied to, for example, various electronic apparatuses including an imaging device such as a digital still camera and a digital video camera, a mobile phone having the imaging function, or other devices having the imaging function.

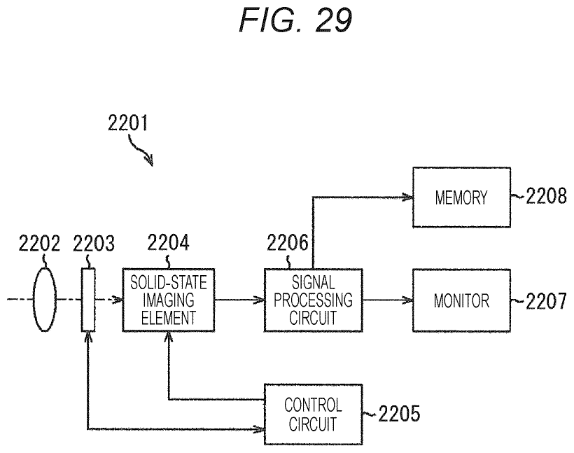

FIG. 29 is a block diagram depicting a configuration example of an imaging device as the electronic apparatus to which the present technology is applied.

An imaging device 2201 in FIG. 29 includes an optical system 2202, a shutter device 2203, a solid-state imaging element 2204 as a photodetector device, a control circuit 2205, a signal processing circuit 2206, a monitor 2207, and two memories 2208 and can capture a still image and a moving image.

The optical system 2202 includes one or a plurality of lenses and guides light from a subject (incident light) to the solid-state imaging element 2204 to form an image on a light receiving surface of the solid-state imaging element 2204.

The shutter device 2203 is arranged between the optical system 2202 and the solid-state imaging element 2204 and controls a light irradiation period and a light shielding period for the solid-state imaging element 2204 under the control of the control circuit 2205.

The solid-state imaging element 2204 includes a package including the solid-state imaging element described above. The solid-state imaging element 2204 accumulates signal charges for a certain period according to light formed on the light receiving surface via the optical system 2202 and the shutter device 2203. The signal charges stored in the solid-state imaging element 2204 are transferred in response to a drive signal (timing signal) supplied from the control circuit 2205.

The control circuit 2205 outputs the drive signal to control a transfer operation of the solid-state imaging element 2204 and a shutter operation of the shutter device 2203 to drive the solid-state imaging element 2204 and the shutter device 2203.

The signal processing circuit 2206 performs various types of signal processing on the signal charges output from the solid-state imaging element 2204. An image (image data) obtained by the signal processing circuit 2206 performing the signal processing is supplied to the monitor 2207 to be displayed or is supplied to the memory 2208 to be stored (recorded).

Also in the imaging device 2201 configured as described above, the photodetector devices 1, 1A, 1B, 1C, 1D, 1E, 1F, 1G, 1H, and 1I can be applied instead of the solid-state imaging element 2204 described above.

### Application Example to Mobile Body

The technology according to the present disclosure (present technology) can be applied to various products. For example, the technology according to the present disclosure may be implemented as a device mounted on any type of mobile body such as an automobile, an electric vehicle, a hybrid electric vehicle, a motorcycle, a bicycle, a personal mobility, an airplane, a drone, a ship, and a robot.

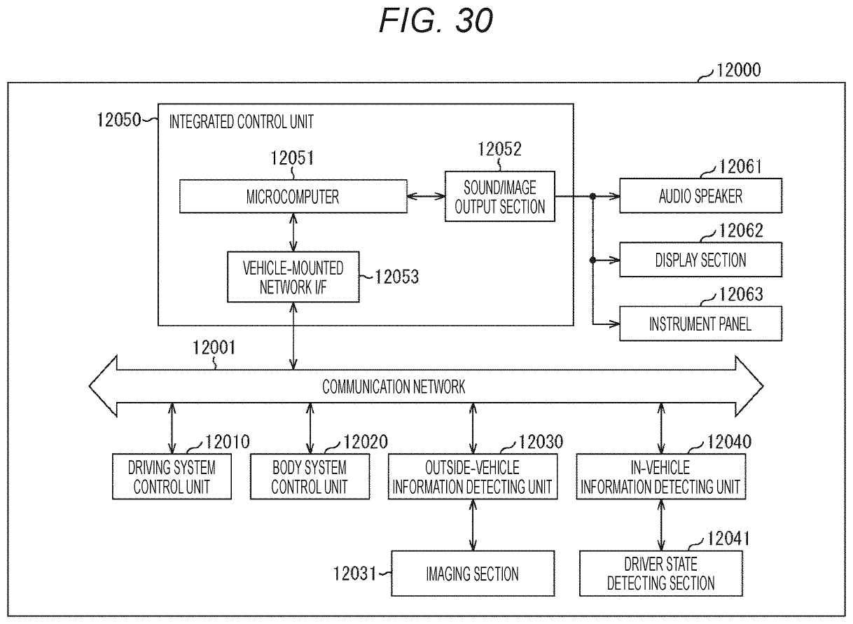

FIG. 30 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 30, the vehicle control system 12000 includes a driving system control unit 12010, a body system control unit 12020, an outside-vehicle information detecting unit 12030, an in-vehicle information detecting unit 12040, and an integrated control unit 12050. Further, a microcomputer 12051, a sound/image output section 12052, and a vehicle-mounted network interface (I/F) 12053 are depicted as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside- vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Further, the microcomputer 12051 can output a control command to the body system control unit 12020 on the basis of the information about the outside of the vehicle obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 30, an audio speaker 12061, a display section 12062, and an instrument panel 12063 are depicted as the output device. The display section 12062 may, for example, include at least one of an on-board display and a head-up display.

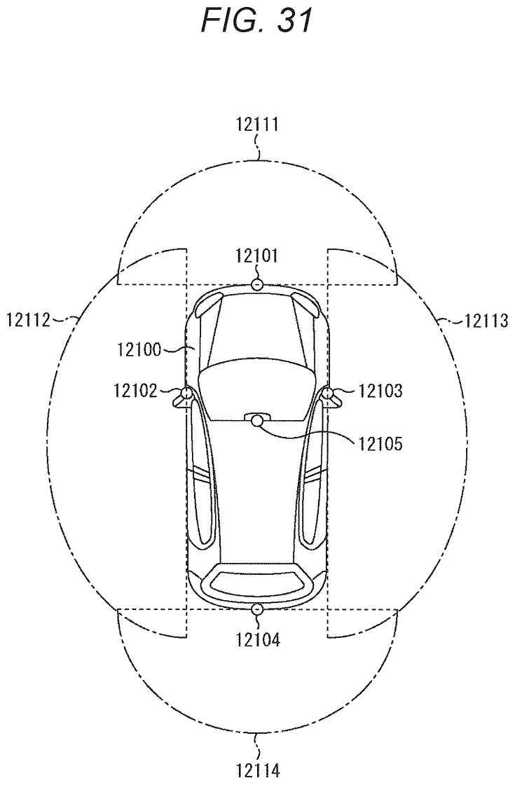

FIG. 31 is a diagram depicting an example of the installation position of the imaging section 12031.

In FIG. 31, a vehicle 12100 includes imaging sections 12101, 12102, 12103, 12104, and 12105 as the imaging section 12031.

The imaging sections 12101, 12102, 12103, 12104, and 12105 are arranged at, for example, positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The images of the front thereof obtained by the imaging sections 12101 and 12105 are mainly used to detect a preceding vehicle, a pedestrian, an obstacle, a traffic signal, a traffic sign, a lane, and the like.

Note that FIG. 31 depicts an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 and the like, for example, among the configurations described above. Specifically, the technology can be applied to the photodetector device 1 in FIG. 1.

Note that the present disclosure can also have the following configurations.
(1)

A semiconductor device including:
a semiconductor substrate; and
a field-effect transistor provided on the semiconductor substrate, in which:
the field-effect transistor includes
a diffusion layer region in which a channel is formed,
a gate electrode portion covering at least a part of the diffusion layer region and having a side wall portion facing a side surface of the diffusion layer region and a top plate portion facing an upper surface of the diffusion layer region,
a source region provided in the diffusion layer region and connected to one side of the gate electrode portion in a gate length direction of the gate electrode portion, and
a drain region provided in the diffusion layer region and connected to the other side of the gate electrode portion in the gate length direction of the gate electrode portion;
the side wall portion and the top plate portion of the gate electrode portion have a self- aligned structure; and
the source region and the drain region are formed to be self-aligned by implanting impurities obliquely into the side wall portion of the gate electrode portion.
(2)

The semiconductor device according to (1), in which
a side wall is provided in each of side wall portions of the source region and the drain region in the diffusion layer region.
(3)

The semiconductor device according to (1), in which
the top plate portion of the gate electrode portion has a larger film thickness than the side wall portion of the gate electrode portion.
(4)

The semiconductor device according to (1), in which
the semiconductor substrate includes a plurality (two or more) of the field-effect transistors arranged to have channels in a same direction.
(5)

The semiconductor device according to (4), in which
diffusion layer regions of the plurality of field-effect transistors are arranged at equal intervals.
(6)

The semiconductor device according to (4), in which
the film thickness of the top plate portion of the gate electrode portion of each of the plurality of field-effect transistors is larger than a half value of a space between the plurality of diffusion layer regions.
(7)

A photodetector device including:
a first substrate portion including a photoelectric conversion element; and
a second substrate portion layered on a surface of the first substrate portion, the surface being opposite to a light incident surface of the first substrate portion, and including a readout circuit that outputs a pixel signal based on a charge output from the photoelectric conversion element, in which:
a field-effect transistor provided in the readout circuit includes
a diffusion layer region in which a channel is formed,
a gate electrode portion covering at least a part of the diffusion layer region and having a side wall portion facing a side surface of the diffusion layer region and a top plate portion facing an upper surface of the diffusion layer region,
a source region provided in the diffusion layer region and connected to one side of the gate electrode portion in a gate length direction of the gate electrode portion, and
a drain region provided in the diffusion layer region and connected to the other side of the gate electrode portion in the gate length direction of the gate electrode portion;
the side wall portion and the top plate portion of the gate electrode portion have a self-aligned structure; and
the source region and the drain region are formed to be self-aligned by implanting impurities obliquely into the side wall portion of the gate electrode portion.
(8)

The photodetector device according to (7), further including
a through contact that connects the first substrate portion and the second substrate portion, in which
the second substrate portion includes
a silicon layer facing the first substrate portion, and
a contact etching stop layer layered on a side of the silicon layer opposite to the first substrate portion.
(9)

The photodetector device according to (7), in which
a side wall is provided in each of side wall portions of the source region and the drain region in the diffusion layer region.
(10)

The photodetector device according to (7), in which
the top plate portion of the gate electrode portion has a larger film thickness than the side wall portion of the gate electrode portion.
(11)

The photodetector device according to (7), in which
in the second substrate portion, a plurality (two or more) of the field-effect transistors is arranged to have channels in a same direction.
(12)

The photodetector device according to (11), in which
diffusion layer regions of the plurality of field-effect transistors are arranged at equal intervals.
(13)

The photodetector device according to (11), in which
the film thickness of the top plate portion of the gate electrode portion of each of the plurality of field-effect transistors is larger than a half value of a space between the plurality of diffusion layer regions.
(14)

The photodetector device according to (7), further including
a through contact that connects the first substrate portion and the second substrate portion, in which:
the diffusion layer region, the source region, and the drain region have a first conductivity type;
a side wall is provided in each of side wall portions of the source region and the drain region in the diffusion layer region; and
the through contact is in direct contact with the side wall.
(15)

The photodetector device according to (7), further including
a through contact that connects the first substrate portion and the second substrate portion, in which:
the diffusion layer region, the source region, and the drain region have a first conductivity type;
a side wall is provided in each of side wall portions of the source region and the drain region in the diffusion layer region; and
the second substrate portion includes a pre metal dielectric (PMD) having a single-layer structure.
(16)

The photodetector device according to (15), in which only one side of the through contact is in contact with the side wall.
(17)

The photodetector device according to (7), in which:
the first substrate portion has a structure without silicide and has a first conductivity type region and a second conductivity type region; and
the second substrate portion has only the first conductivity type region in a pixel region including the readout circuit.
(18)

The photodetector device according to (17), in which
the field-effect transistor is a fully-depleted field-effect transistor.
(19)

The photodetector device according to (17), in which
the field-effect transistor has a fin structure.
(20)

The photodetector device according to (19), in which in the field-effect transistor, a bottom portion of the gate electrode portion is deeper than a bottom portion of the diffusion layer region.
(21)

The photodetector device according to (17), in which
a wire connected to the second conductivity type region is not connected to the second substrate portion at least in the pixel region.
(22)

The photodetector device according to (21), in which
the wire connected to the second conductivity type region penetrates the second substrate portion outside the pixel region.
(23)

The photodetector device according to (22), in which
the wire connected to the second conductivity type region penetrates the first substrate portion inside the pixel region.
(24)

The photodetector device according to (7), further including
a gate insulation film arranged between the diffusion layer region and the gate electrode portion.
(25)

An electronic apparatus including
a photodetector device including
a first substrate portion including a photoelectric conversion element, and
a second substrate portion layered on a surface of the first substrate portion, the surface being opposite to a light incident surface of the first substrate portion, and including a readout circuit that outputs a pixel signal based on a charge output from the photoelectric conversion element, in which:
a field-effect transistor provided in the readout circuit includes
a diffusion layer region in which a channel is formed,
a gate electrode portion covering at least a part of the diffusion layer region and having a side wall portion facing a side surface of the diffusion layer region and a top plate portion facing an upper surface of the diffusion layer region,
a source region provided in the diffusion layer region and connected to one side of the gate electrode portion in a gate length direction of the gate electrode portion, and
a drain region provided in the diffusion layer region and connected to the other side of the gate electrode portion in the gate length direction of the gate electrode portion;
the side wall portion and the top plate portion of the gate electrode portion have a self- aligned structure; and
the source region and the drain region are formed to be self-aligned by implanting impurities obliquely into the side wall portion of the gate electrode portion.

### REFERENCE SIGNS LIST

1, 1A, 1B, 1C, 1D, 1E, 1F, 1G, 1H, 1I Photodetector device
10 First substrate
11 First semiconductor substrate
11a Front surface
12 Sensor pixel
13 Pixel region
14 Fin portion
20 Second substrate
21 Second semiconductor substrate
21a Front surface
21b Back surface
22, 22A, 22B, 22C, 22D, 22E Readout circuit
23 Pixel drive line
24 Vertical signal line
30 Third substrate
31 Third semiconductor substrate
32 Logic circuit
33 Vertical drive circuit
34 Column signal processing circuit
35 Horizontal drive circuit
36 System control circuit
51 High-concentration n-type layer (n-type diffusion layer)
52 High-concentration p-type layer (p-type diffusion layer)
53 p-well
54 n-type layer
55 Pixel isolation layer
56 p-type layer
57 n-type layer
58, 82 Interlayer insulation film
71 p-well
72 Element isolation layer
73 High-concentration p-type layer
74, 76 Drain portion
75, 77 Source portion
78 High-concentration n-type layer
79 High-concentration n-type layer
110 Substrate
111, 112, 113, 115, 116, 119, 201, 311, 312, 313, 314 Fin portion
112a, 113a, 113b Side wall portion
114, 117, 118, 321, 322, 324, 331, 332, 333, 341, 342, 343 Through contact
202 Gate electrode material
410 First substrate
411 First semiconductor substrate
411a Front surface
420 Second substrate
451 High-concentration n-type layer (n+-type diffusion layer)
452 High-concentration p-type layer (p-type diffusion layer)
453 n-type layer
454 n—type layer
458 Insulation film
474 Fin portion
478 Drain portion
479 Source portion
481 Insulation film
490 Well tap portion
491 High-concentration p-type layer
492 Low-concentration p-type layer
501 Gate electrode
502 Diffusion layer
510 First substrate
510a Front surface
520 Second substrate
520a Front surface
520b Back surface
531 Pixel region
532 Bonding pad portion
533 Conductive material
551 High-concentration n-type layer
552 High-concentration p-type layer
553 p-type layer
554 n-type layer
555 Pixel isolation layer
610, 710 Conductive material
810 Through contact
2201 Imaging device
2202 Optical system
2203 Shutter device
2204 Solid-state imaging element
2205 Control circuit
2206 Signal processing circuit
2207 Monitor
2208 Memory
12000 Vehicle control system
12001 Communication network
12010 Driving system control unit
12020 Body system control unit
12030 Outside-vehicle information detecting unit
12031 Imaging section
12040 In-vehicle information detecting unit
12041 Driver state detecting section
12050 Integrated control unit
12051 Microcomputer
12052 Sound/image output section
12061 Audio speaker
12062 Display section
12063 Instrument panel
12100 Vehicle
12101 to 12105 Imaging section
12111 to 12114 Imaging range

What is claimed is:

1. A semiconductor device, comprising:
a semiconductor substrate; and
a field-effect transistor provided on the semiconductor substrate, wherein:
the field-effect transistor includes
a diffusion layer region in which a channel is formed,
a gate electrode portion covering at least a part of the diffusion layer region and having a side wall portion facing a side surface of the diffusion layer region and a top plate portion facing an upper surface of the diffusion layer region,
a source region provided in the diffusion layer region and connected to one side of the gate electrode portion in a gate length direction of the gate electrode portion, and
a drain region provided in the diffusion layer region and connected to the other side of the gate electrode portion in the gate length direction of the gate electrode portion;
the side wall portion and the top plate portion of the gate electrode portion have a self-aligned structure; and
the source region and the drain region are formed to be self-aligned by implanting impurities obliquely into the side wall portion of the gate electrode portion.

2. The semiconductor device according to claim 1, wherein
a side wall is provided in each of side wall portions of the source region and the drain region in the diffusion layer region.

3. The semiconductor device according to claim 1, wherein
the top plate portion of the gate electrode portion has a larger film thickness than the side wall portion of the gate electrode portion.

4. The semiconductor device according to claim 1, wherein
the semiconductor substrate includes a plurality (two or more) of the field-effect transistors arranged to have channels in a same direction.

5. The semiconductor device according to claim 4, wherein
diffusion layer regions of the plurality of field-effect transistors are arranged at equal intervals.

6. The semiconductor device according to claim 4, wherein
the film thickness of the top plate portion of the gate electrode portion of each of the plurality of field-effect transistors is larger than a half value of a space between the plurality of diffusion layer regions.

7. A photodetector device, comprising:
a first substrate portion including a photoelectric conversion element; and
a second substrate portion layered on a surface of the first substrate portion, the surface being opposite to a light incident surface of the first substrate portion, and including a readout circuit that outputs a pixel signal based on a charge output from the photoelectric conversion element, wherein:
a field-effect transistor provided in the readout circuit includes
a diffusion layer region in which a channel is formed,
a gate electrode portion covering at least a part of the diffusion layer region and having a side wall portion facing a side surface of the diffusion layer region and a top plate portion facing an upper surface of the diffusion layer region,
a source region provided in the diffusion layer region and connected to one side of the gate electrode portion in a gate length direction of the gate electrode portion, and
a drain region provided in the diffusion layer region and connected to the other side of the gate electrode portion in the gate length direction of the gate electrode portion;
the side wall portion and the top plate portion of the gate electrode portion have a self-aligned structure; and
the source region and the drain region are formed to be self-aligned by implanting impurities obliquely into the side wall portion of the gate electrode portion.

8. The photodetector device according to claim 7, further comprising
a through contact that connects the first substrate portion and the second substrate portion, wherein
the second substrate portion includes
a silicon layer facing the first substrate portion, and
a contact etching stop layer layered on a side of the silicon layer opposite to the first substrate portion.

9. The photodetector device according to claim 7, wherein
a side wall is provided in each of side wall portions of the source region and the drain region in the diffusion layer region.

10. The photodetector device according to claim 7, wherein
the top plate portion of the gate electrode portion has a larger film thickness than the side wall portion of the gate electrode portion.

11. The photodetector device according to claim 7, wherein
in the second substrate portion, a plurality (two or more) of the field-effect transistors is arranged to have channels in a same direction.

12. The photodetector device according to claim 11, wherein
diffusion layer regions of the plurality of field-effect transistors are arranged at equal intervals.

13. The photodetector device according to claim 11, wherein
the film thickness of the top plate portion of the gate electrode portion of each of the plurality of field-effect transistors is larger than a half value of a space between the plurality of diffusion layer regions.

14. The photodetector device according to claim 7, further comprising
a through contact that connects the first substrate portion and the second substrate portion, wherein:
the diffusion layer region, the source region, and the drain region have a first conductivity type;
a side wall is provided in each of side wall portions of the source region and the drain region in the diffusion layer region; and
the through contact is in direct contact with the side wall.

15. The photodetector device according to claim 7, further comprising
a through contact that connects the first substrate portion and the second substrate portion, wherein:
the diffusion layer region, the source region, and the drain region have a first conductivity type;
a side wall is provided in each of side wall portions of the source region and the drain region in the diffusion layer region; and
the second substrate portion includes a pre metal dielectric (PMD) having a single-layer structure.

16. The photodetector device according to claim 15, wherein
only one side of the through contact is in contact with the side wall.

17. The photodetector device according to claim 7, wherein:
the first substrate portion has a structure without silicide and has a first conductivity type region and a second conductivity type region; and
the second substrate portion has only the first conductivity type region in a pixel region including the readout circuit.

18. The photodetector device according to claim 17, wherein
the field-effect transistor is a fully-depleted field-effect transistor.

19. The photodetector device according to claim 17, wherein
the field-effect transistor has a fin structure.

20. The photodetector device according to claim 19, wherein in the field-effect transistor, a bottom portion of the gate electrode portion is deeper than a bottom portion of the diffusion layer region.

21. The photodetector device according to claim 17, wherein
a wire connected to the second conductivity type region is not connected to the second substrate portion at least in the pixel region.

22. The photodetector device according to claim 21, wherein
the wire connected to the second conductivity type region penetrates the second substrate portion outside the pixel region.

23. The photodetector device according to claim 22, wherein
the wire connected to the second conductivity type region penetrates the first substrate portion inside the pixel region.

24. The photodetector device according to claim 7, further comprising
a gate insulation film arranged between the diffusion layer region and the gate electrode portion.

25. An electronic apparatus, comprising
a photodetector device including
a first substrate portion including a photoelectric conversion element, and
a second substrate portion layered on a surface of the first substrate portion, the surface being opposite to a light incident surface of the first substrate portion, and including a readout circuit that outputs a pixel signal based on a charge output from the photoelectric conversion element, wherein:
a field-effect transistor provided in the readout circuit includes
a diffusion layer region in which a channel is formed,
a gate electrode portion covering at least a part of the diffusion layer region and having a side wall portion facing a side surface of the diffusion layer region and a top plate portion facing an upper surface of the diffusion layer region,
a source region provided in the diffusion layer region and connected to one side of the gate electrode portion in a gate length direction of the gate electrode portion, and
a drain region provided in the diffusion layer region and connected to the other side of the gate electrode portion in the gate length direction of the gate electrode portion;
the side wall portion and the top plate portion of the gate electrode portion have a self-aligned structure; and
the source region and the drain region are formed to be self-aligned by implanting impurities obliquely into the side wall portion of the gate electrode portion.
